(19) United States
(12) Patent Application Publication
(10) Pub. No.: US 2010/0149418 A1
(43) Pub. Date: Jun. 17, 2010

(54) VIDEO IMPROVEMENT PROCESSOR

(75) Inventors: Karol Freed, Thousand Oak, CA (US); Randy L. Burnworth, Denton, TX (US); Vernon Bushway, Trabuco Canyon, CA (US)

Correspondence Address: DOCKET CLERK, P.O. DRAWER 800889, DALLAS, TX, 75380, US

(73) Assignee: Shomi Technologies Corporation, Denton, TX (US)

(21) Appl. No.: 12/558,205

(22) Filed: Sep. 11, 2009

Related U.S. Application Data
(63) Continuation-in-part of application No. 10/665,930, filed on Sep. 19, 2003.
(60) Provisional application No. 60/412,357, filed on Sep. 21, 2002.

(51) Int. Cl. H04N 9/77; H03M 1/12

(52) U.S. Cl. 348/572; 348/663; 348/E03.012; 348/E09.035

(57) ABSTRACT

A video device includes a video processor operable to upgrade a video image. The video device is capable of displaying video images. The video device includes a video input configured to receive a composite video signal. The composite video signal includes synchronization information, both vertical and horizontal, a luminance and a chrominance. The video device includes a video processor configured to separate the composite signal into separate paths. The video processor is configured to perform video functions on the separate paths individually and combine the separate paths to produce an upgraded video image. The video device also includes a video output configured to receive the upgraded video imaged from the video processor and output the upgraded video image to a display.

### CROSS-REFERENCE TO RELATED APPLICATION(S) AND CLAIM OF PRIORITY

The present application is related to U.S. Provisional Patent Application No. 61/096,260, filed Sep. 11, 2008, entitled “VIDEO IMPROVEMENT PROCESSOR”. Provisional Patent Application No. 61/096,260 is assigned to the assignee of the present application and is hereby incorporated by reference into the present application as if fully set forth herein. The present application hereby claims priority under 35 U.S.C. §119(e) to U.S. Provisional Patent Application No. 61/096,260.

The present application is a related to U.S. patent application Ser. No. 10/665,930, entitled “SWITCHED INPUT VIDEO DEIVCE,” filed on Sep. 19, 2003. application Ser. No. 10/665,930 is assigned to the assignee of the present application and is hereby incorporated by reference into the present application as if fully set forth herein. The present application hereby claims priority under 35 U.S.C. §120 to U.S. patent application Ser. No. 10/665,930.

### TECHNICAL FIELD OF THE INVENTION

The present application relates generally to video processing and, more specifically, to a system and method for improving the quality of a video image.

### BACKGROUND OF THE INVENTION

Video systems for use in broadcast television, cable television, closed circuit television, computer systems and the like are well known. According to such video systems, a video signal from a camera is ultimately provided to a display device, such as a television or computer monitor. Frequently, the video signal is recorded upon a medium, such as videotape, hard drive or a DVD disc, prior to being displayed upon the display device.

The video signal may be generated, stored, and displayed according to one of a number of different standards. The National Television System Committee (NTSC) standard is an example of such standards. The NTSC standard is used in North America and Japan. Other standards, as well as variations of these standards, also exist.

### SUMMARY OF THE INVENTION

An apparatus for use in a system capable of displaying video images is provided. The apparatus includes a video input configured to receive a composite video signal. The composite video signal includes a luminance and a chrominance. The apparatus includes a video processor configured to separate the composite signal into separate paths. The video processor is configured to perform video functions on the separate paths individually and combine the separate paths to produce an upgraded video image. The apparatus also includes a video output configured to receive the upgraded video imaged from the video processor and output the upgraded video image to a display.

A video display system is provided. The video system includes a display. The video system also includes a video input configured to receive a composite video signal. The composite video signal includes a luminance and a chrominance. The video system includes a video processor configured to separate the composite signal into separate paths. The video processor is configured to perform video functions on the separate paths individually and combine the separate paths to produce an upgraded video image. The video system also includes a video output configured to receive the upgraded video imaged from the video processor and output the upgraded video image to a display.

A method for enhancing video is provided. The method includes receiving a video signal according to a standard. The video signal is separated into a number of component signals. The method includes performing special processing on respective component signals; and combining the respective component signals to form an upgraded video signal.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a video device according to embodiments of the present disclosure;

FIG. 2 illustrates a block diagram of the video processor 110 according to embodiments of the present disclosure;

FIG. 3 illustrates a block diagram of the Regeneration/Burst amplifier 236 according to embodiments of the present disclosure;

FIG. 4 illustrates a block diagram for an image enhancement circuit according to embodiments of the present disclosure;

FIG. 5 illustrates a block diagram for a main video channel according to embodiments of the present disclosure;

FIG. 6 illustrates a method for video enhancement according to embodiments of the present disclosure;

FIGS. 7A-7C illustrates a oscilloscope images for Stair-step signals according to embodiments of the present disclosure;

FIG. 8 illustrates another block diagram of the video processor 110 according to embodiments of the present disclosure; and

FIGS. 9A-9D illustrates a schematic diagram of the video processor 110 according to embodiments of the present disclosure.

### DETAILED DESCRIPTION OF THE INVENTION

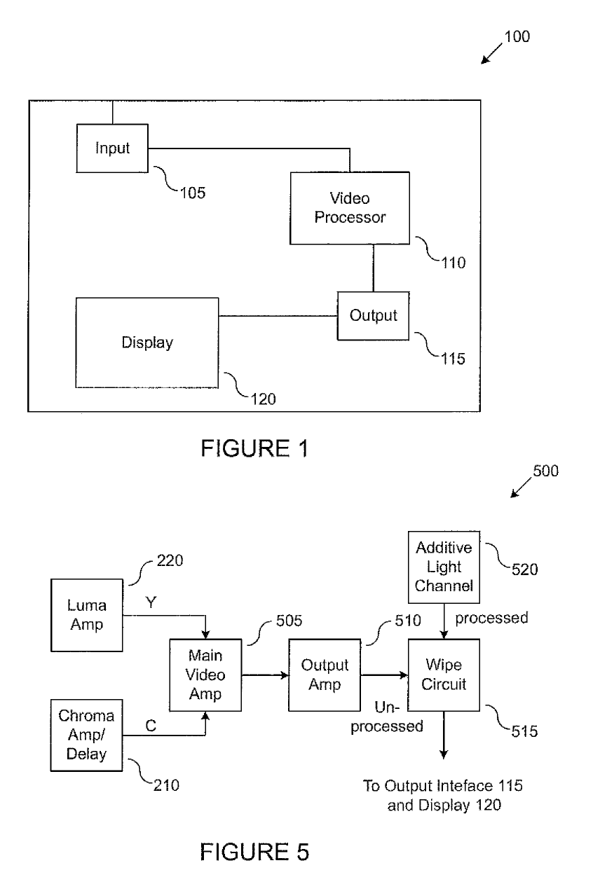

FIGS. 1 through 9D, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged video imaging system.

FIG. 1 illustrates a video device according to embodiments of the present disclosure. The video device 100 shown in FIG. 1 is for illustration only. Other embodiments could be used without departing from the scope of this disclosure.

The video device 100 can be any device capable of rendering video images such as, but not limited to, a television, a personal data assistant, a personal computer, a mobile computer (e.g., a laptop), a mobile telephone, a smart phone, an oscilloscope, a security monitor, a health monitor, video game, video recorder, digital video recorder, compact disc recorder, and the like. In some embodiments, the video device 100 receives a video signal from an external source. In some embodiments, the video device 100 receives the video signal from an internal source such as, but not limited to, one or more sensors, a memory or other computer readable medium, a magnetic media storage device, an optical media storage device, or some other media storage device as is known in the art.

The video signal received by the video device 100 can be a composite signal that includes Color, Video, Blank and Sync (CVBS) components. The composite video signal is a composite of three source signals called Y, C with sync pulses. Y and C are also referred herein as Y, U, V or together referred to as YUV. Y represents the brightness or luminance of the picture and includes synchronizing pulses. Luminance alone could be displayed as a monochrome picture. C (also referred as U and V) represents a hue and saturation or chrominance. The chrominance carries the color information. They are first modulated on two orthogonal phases of a color carrier signal to form a signal called the chrominance. Y and C are then combined. Since Y is a baseband signal and C has been mixed with a carrier, this addition can be equivalent to frequency-division multiplexing.

The video device 100 includes an input interface 105. The input interface 105 can be an interface configured to receive the video signal. For example, the input interface 105 can be a port adapted to be coupled to a video input line. Additionally, the input interface 105 can be an interface configured to receive the video signal from an internal source such as an interface configured to read one of a file from a computer readable medium, a playback mechanism (e.g., magnetic head) configured to read information from a magnetic media storage device, an optical reading device configured to read information from an optical media storage device, and so forth.

The input device 105 is coupled to a video processor 110. The video processor 110 is configured to receive the video signal from the input interface 105. The video processor 110 can separate the composite video signal into a number of separate paths. Thereafter, the video processor 110 can perform a number of respective functions on one or more of the separate paths. The video processor 110 can combine the separate paths, perform additional functions on the combined paths and produce an enhanced, augmented or altered, video signal that is output by output interface 115. Herein, enhance can be add to, adorn, aggrandize, amplify, appreciate, augment, boom, boost, build up, complement, elevate, enlarge, exaggerate, exalt, flesh out, heighten, increase, intensify, lift, magnify, pad, raise, reinforce, strengthen, swell, or upgrade.

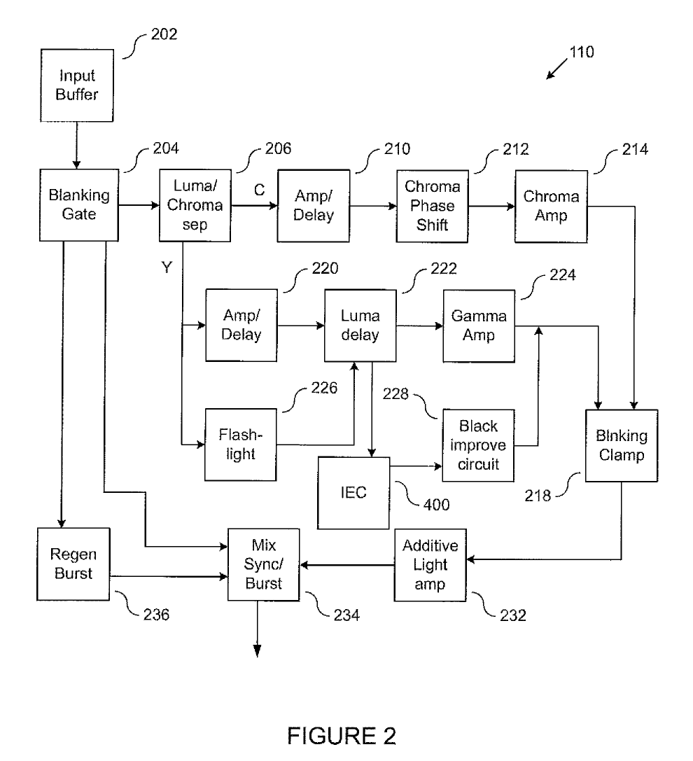

The video processor 110 includes a number of circuits (discussed in further detail herein below with respect to FIGS. 2-9). The video processor 110 is configured to perform a number of functions such as, but not limited to, an additive light function that is designed to be able to increase an amplitude range of the NTSC encoded signal without affecting an amplitude of the synchronizing and color burst information as well as any effects on the systems' differential gain and phase. The increased amplitude range allows for a higher video level to be produced by the video device 100 by the segregation of the composite sync signals, both Vertical, Horizontal, and color burst. Therefore, the NTSC signal is processed as a non-composite signal for amplification and signal processing purposes.

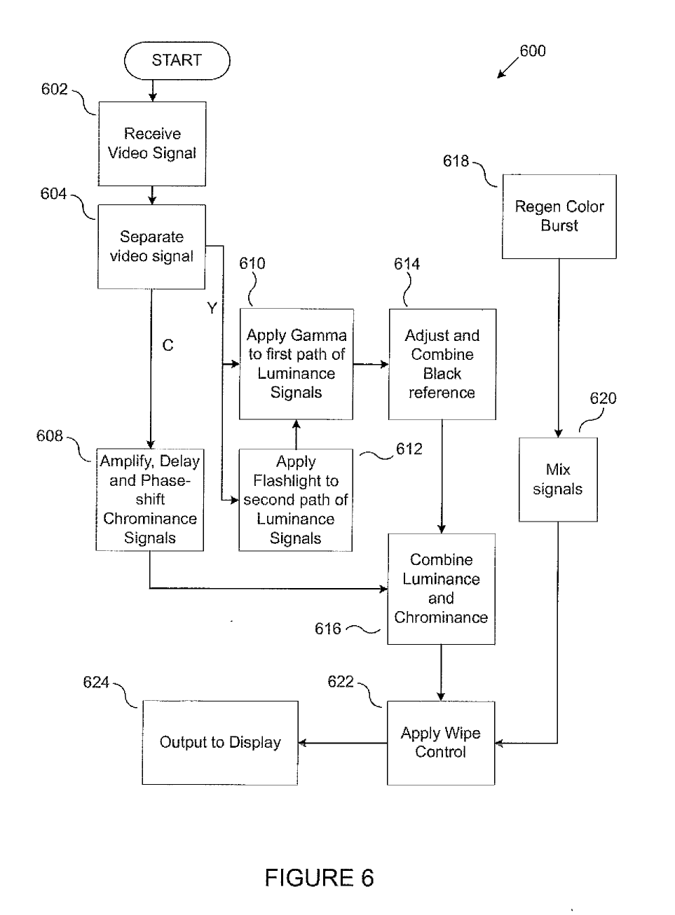

The video processor 110 also can provide a gamma (γ) correction function. The gamma correction function can change the transfer function of the video signal (for example, the slope of the signal or signal linearity). The gamma correction function performed by the video processor 110, however, is a modified “high-knee” gamma function discussed in further detail herein below with respect to FIGS. 2 and 6. The gamma correction function converts the light intensity or voltage level at some voltage points in the video signal that relates to brightness on a display 120.

The video processor 110 further can provide a flashlight (also referred to as a Black Expansion) function that is able to raise a brightness level of certain portions of a video scene, for example, low light levels. Black Expansion differs from the gamma correction function by selectivity expanding the video amplitude only in a certain portions of the video scene, for example, from 0 to 50 on a Institute of Radio Engineers (IRE) unit of measurement, by an adjustable amount while not affecting the gain. The selective expansion can be referred to as a threshold selective expansion.

The output interface 115 sends the enhanced video signal to be rendered by a display 120. The display 120 may be included as part of the video device 100 or the display 120 may be external to the video device 100. For example, the display 120 can be an external monitor that is adapted to couple to video device 100 via output interface 115.

FIG. 2 illustrates a block diagram of the video processor 110 according to embodiments of the present disclosure. The embodiment of the video processor 110 shown in FIG. 2 is for illustration only. Other embodiments could be used without departing from the scope of this disclosure.

The video processor 110 receives the composite video signal and processes the composite video signal through an input buffer 202 and amplifier. The composite video signal includes vertical and horizontal synchronization information, color burst, luminance and chrominance. The composite signal is buffered by a buffer amplifier (not specifically illustrated) and clamped hard to a DC baseline.

Thereafter, a video switch 204, also referred to as a blanking gate, separates both the horizontal and vertical synchronization information and color burst from the composite video signal. The video switch 204 can be a high/low crossover R/C/L network that separates the noncomposite encoded video signal into, inter alia, Luminance (LUMA) and Chrominance (CHROMA) components as well as sync and color burst information. Therefore, the composite video signal can be separated into a sync path, color burst path, and Y-C (luma-chroma) path. The video switch 204 can be a high speed video switch. The output of the video switch 204 can be a first modified video signal that includes luminance (Y) and chrominance (C) and vertical and horizontal blanking information.

The modified signal output from the video switch 204, is processed by a luma/chroma separator 206. For example, the luma/chroma separator 206 can include a High Pass Filter (HPF) configured to eliminate the luminance and output the chrominance on a first path output. Additionally, the luma/chroma separator 206 can include a Low Pass Filter (LPF) to eliminate the chrominance and output the luminance on a second path output. The luma/chroma separator 206 is configured to separate the luminance (Y) and chrominance (C). Accordingly, the luma/chroma separator 206 further separates the Y-C path into a luma signal (or luma channel or path) and a chroma signal (or chroma channel or path). The luma signal and chroma signal are each further routed for special function processing.

The chroma signal is processed by an amp/delay circuit 210. The amp/delay circuit 210 can include one or more amplifiers, one or more buffers, and a plurality of delay circuits. The plurality of delay circuits can provide a delay for timing reasons to synchronize the chroma signal with another path that undergoes more processing steps. The amp/delay circuit 210 can include a chroma inverter that inverts the chroma signal that feeds a chroma delay.

Thereafter, the chroma signal undergoes a phase shift by Chroma phase-shifter 212. Chroma phase-shifter 212 can shift the phase of the chroma signal by up to three-hundred sixty degrees) (360°. Therefore, the phase of the colors is phase shifted to enhance information and detail for better viewing on the display 120.

A chroma amp 214 amplifies the phase shifted chroma signal. The chroma amp 214 provides a gain to the chroma signal under the control of a Direct Current (DC) gain control. The chroma amp 214 can be DC controlled. As such, the chroma amp 214 can include or be coupled to a control that applies a DC voltage to vary the gain of the chroma amp 214. Therefore, a potentiometer may not be required to vary the gain. Since the chroma signal does not include synchronization information (e.g., running a non-composite signal), the gain of the chroma amp 214 can be raised substantially without affecting the sync signal by clipping or compression. The output from the chroma amp 214 is input to a blanking clamp 218. The blanking clamp 218 can be a high speed video switch that includes a resistive network at the input. The resistive network can be configured to combine the chroma and luma signals. The blanking clamp 218 can clamp the horizontal blanking.

The luma signal is processed by an amp circuit 220. The amp circuit 220 can include one or more amplifiers. Thereafter, the luma signal undergoes a delay by a luma delay amplifier 222 for signal timing purposes. A gamma correction function can be performed on the output of the luma delay amplifier 222. A gamma amplifier 224 is configured to perform the gamma correction function. The gamma function can be a modified gamma function that incorporates a “high-knee” in a parabolic wave form function. The gamma amplifier 224 can be a Direct Current (DC) controlled gamma correction amplifier that is configured to allow an amount of gamma correction to be adjusted from linear (e.g., no correction) to maximum gamma correction by applying ‘0’ to ‘2.5’ volts DC. The gamma amplifier 224 uses a combining feature to produce a parabolic wave shape. Nominal black stretch (gamma correction) is 4:1 from blanking to the knee at 15 IRE units video amplitude. The output of the gamma amplifier then can be combined with the chromo signal in the blanking clamp 218.

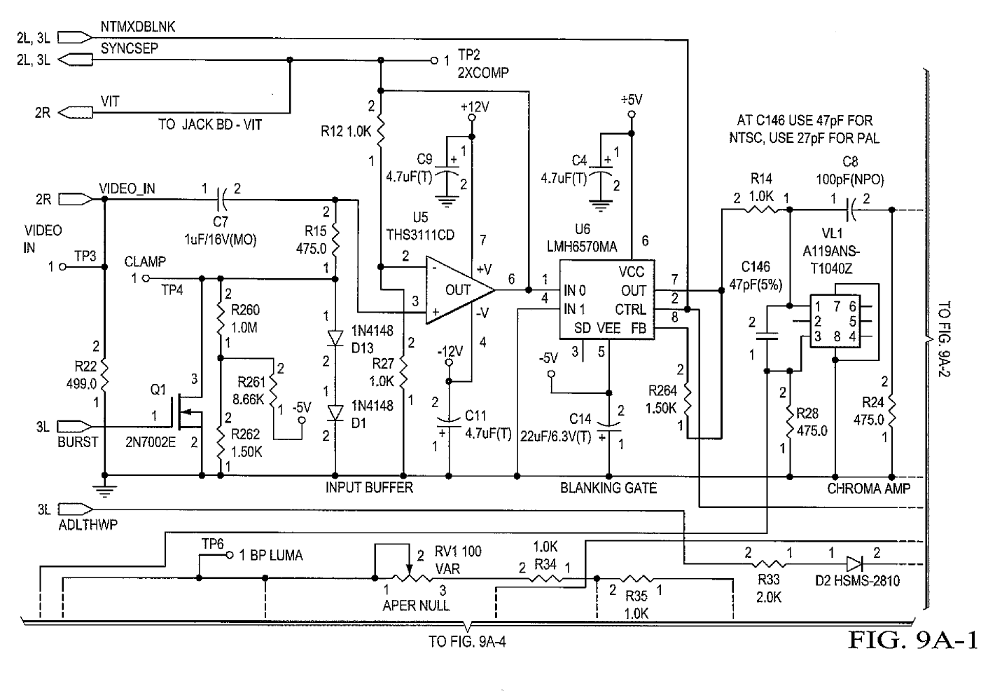

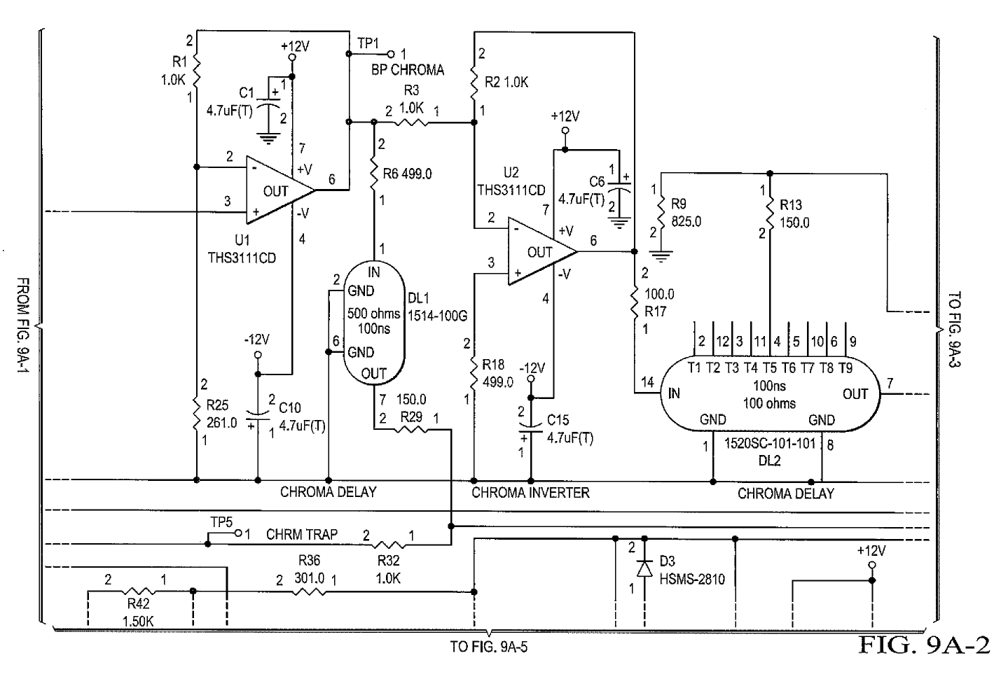

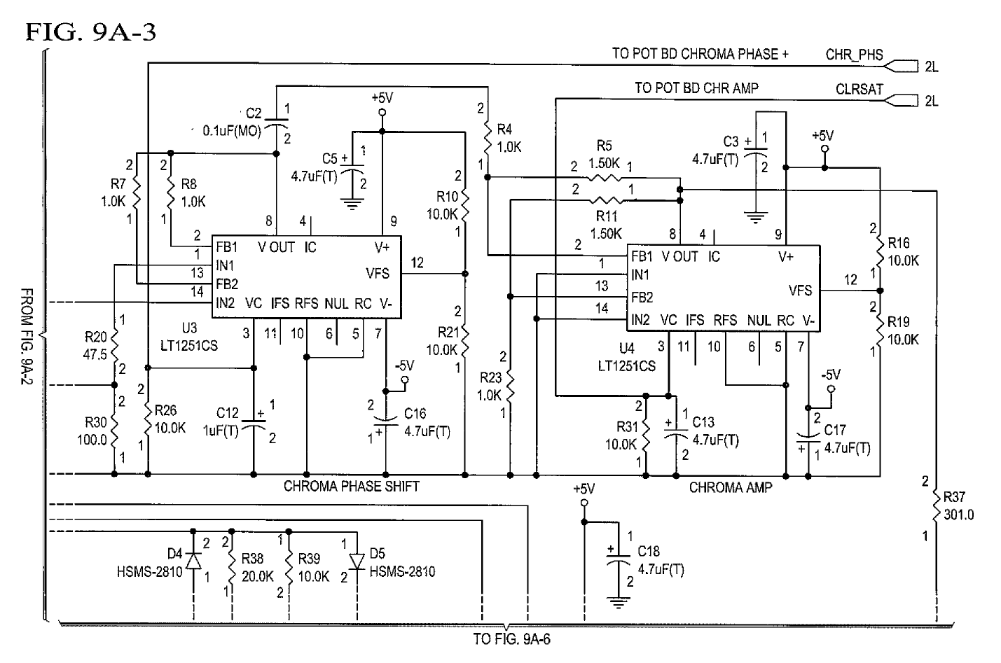

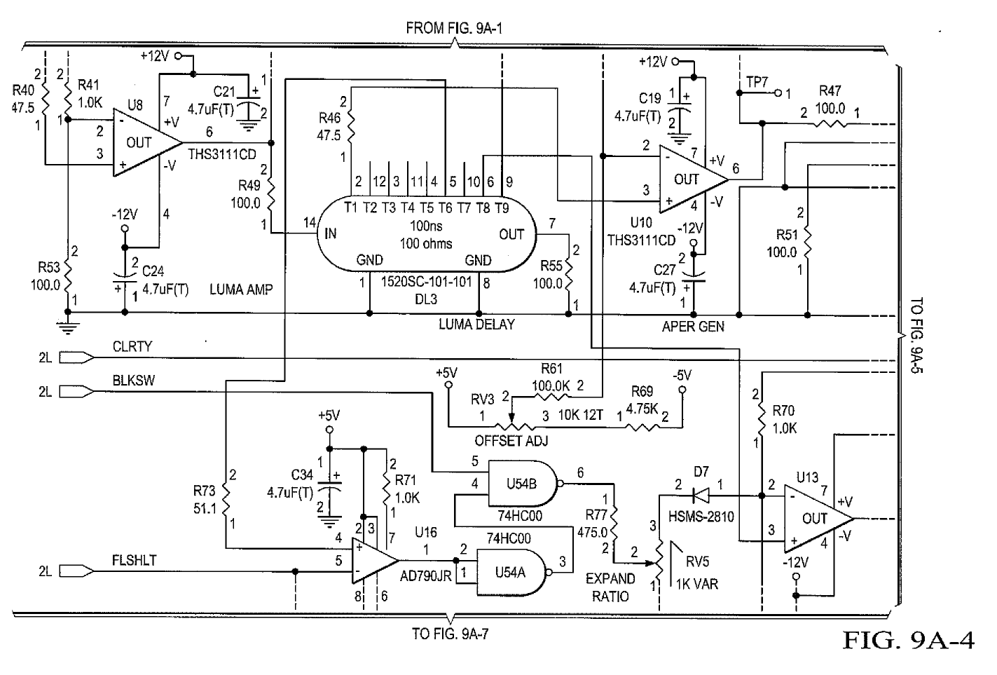

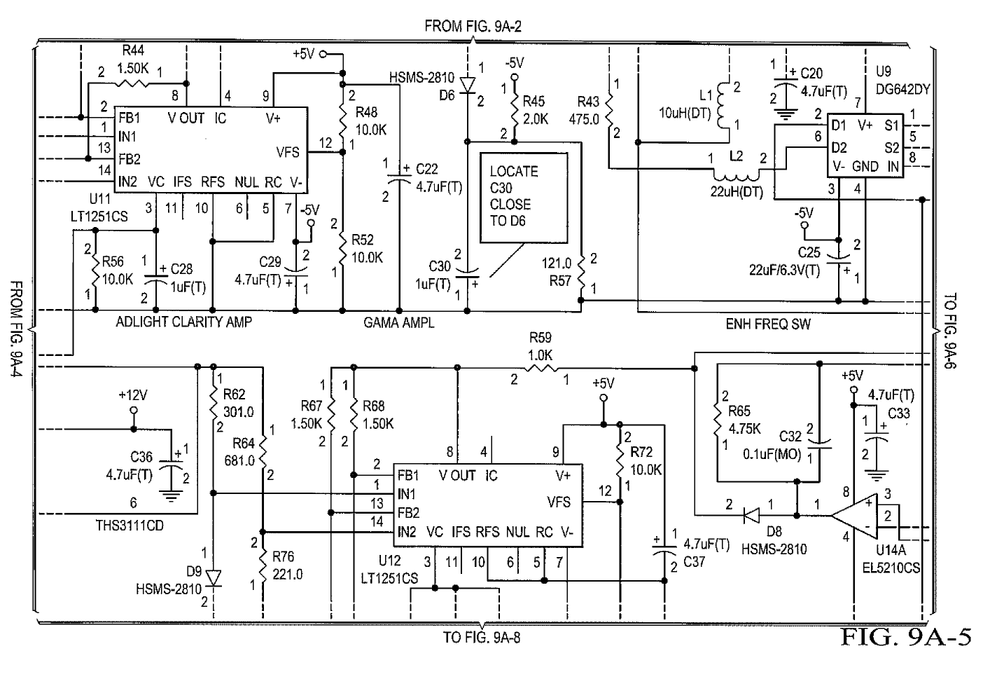

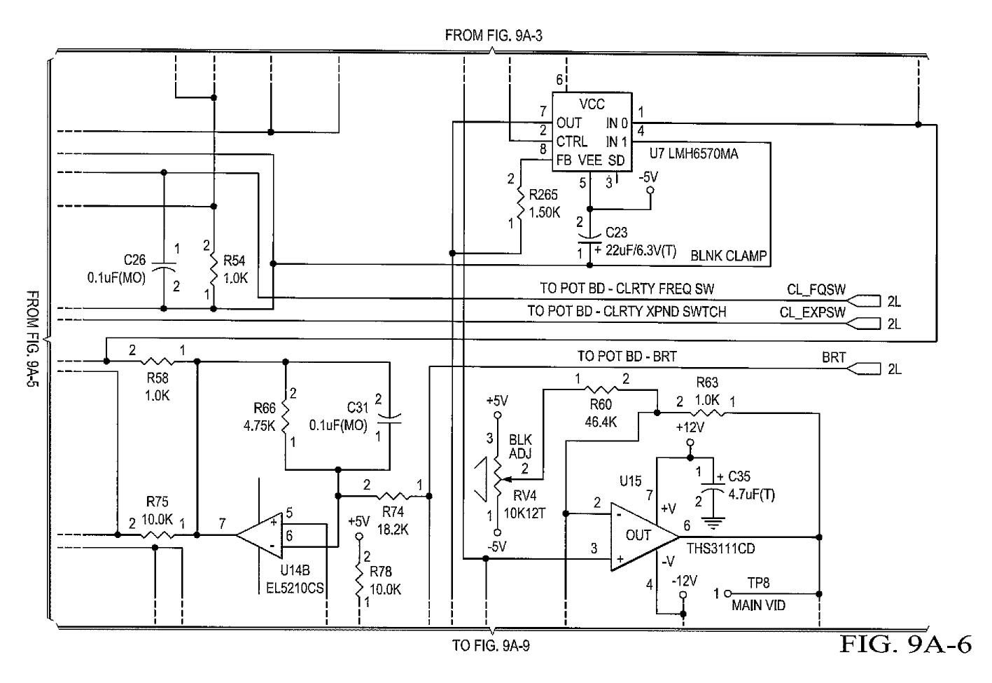

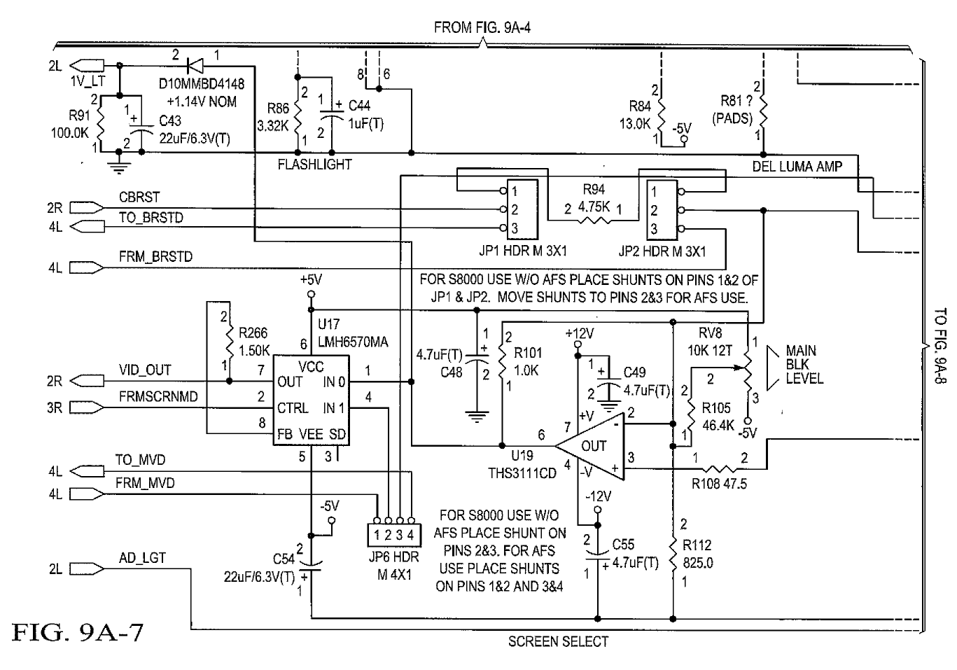

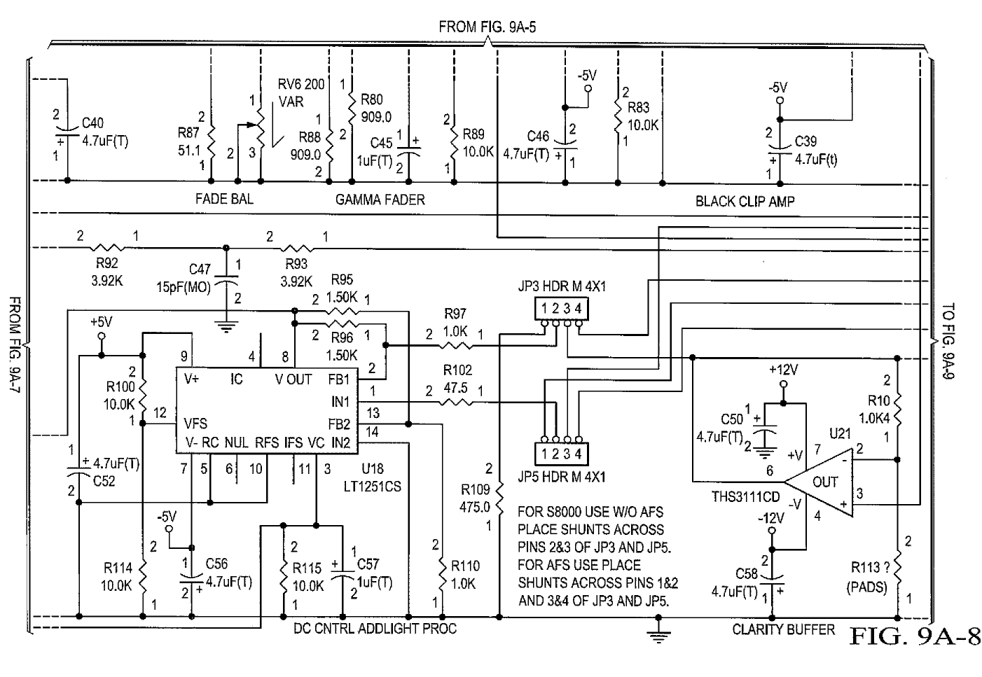

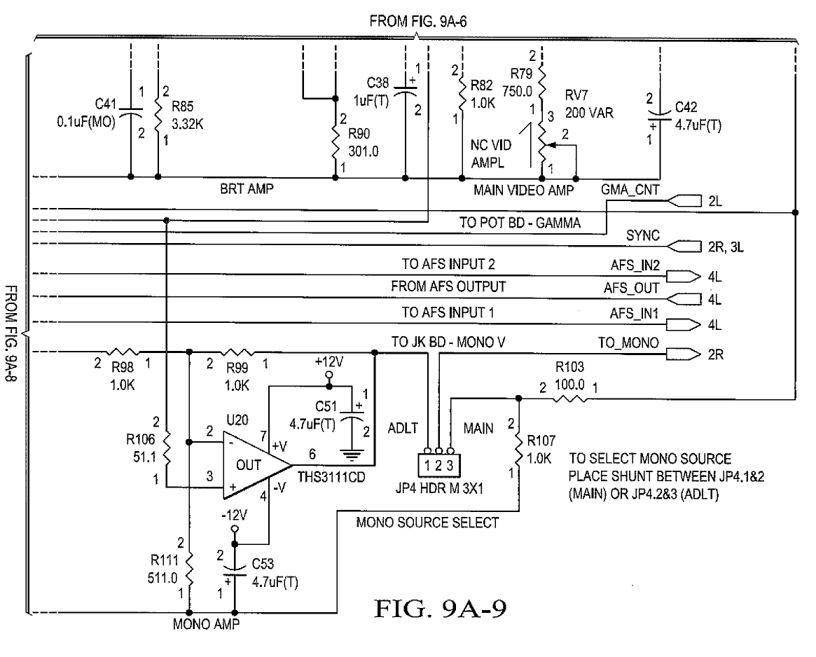

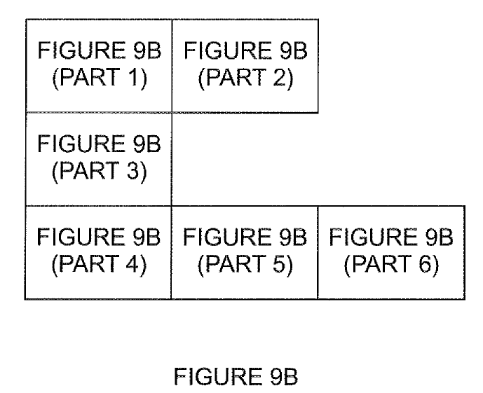

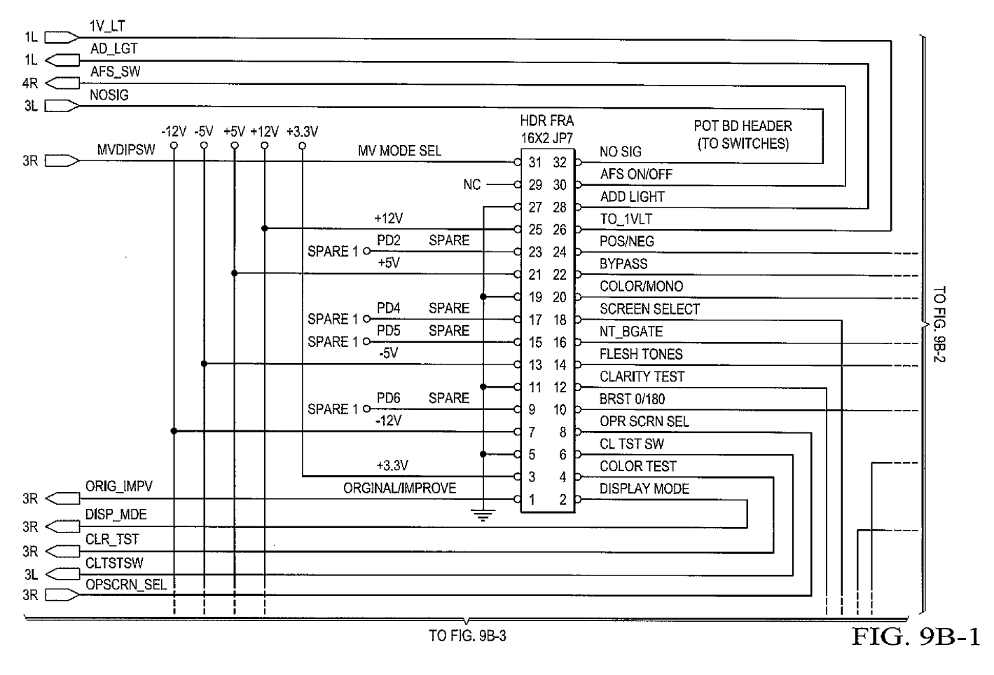

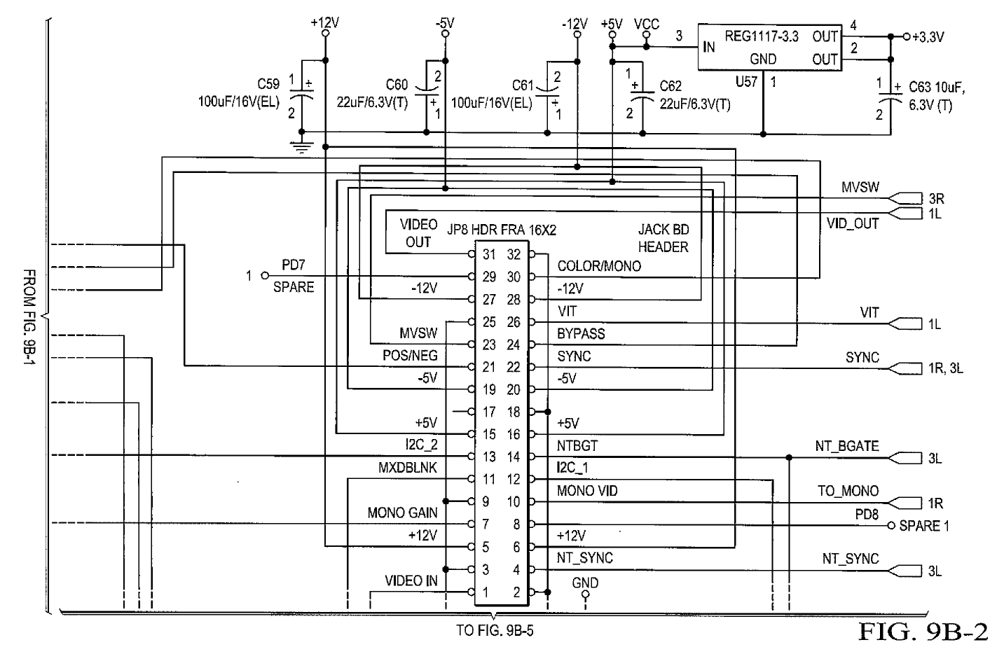

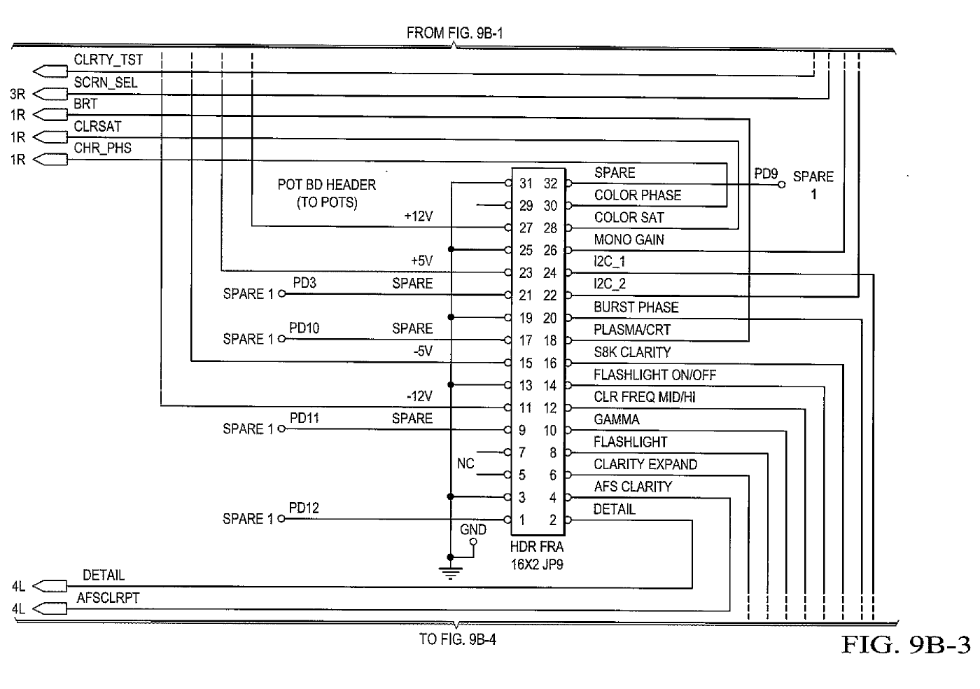

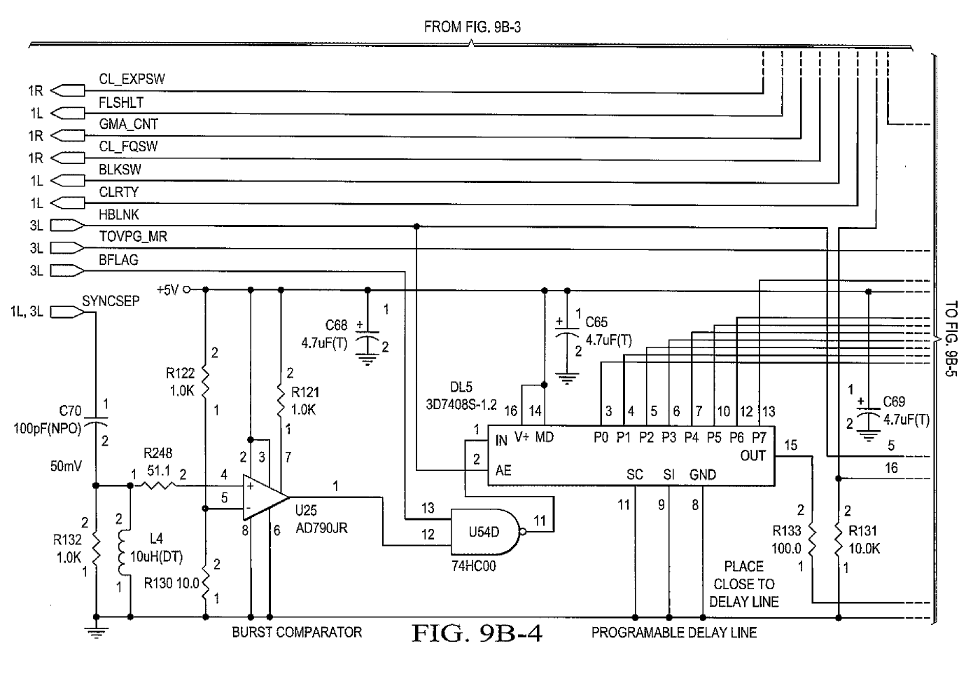

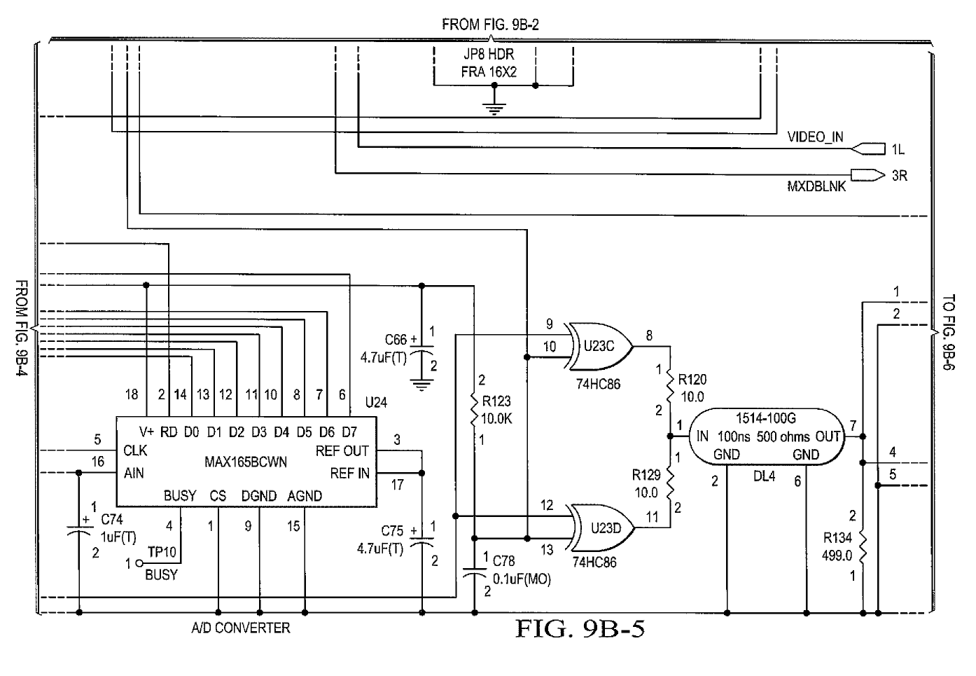

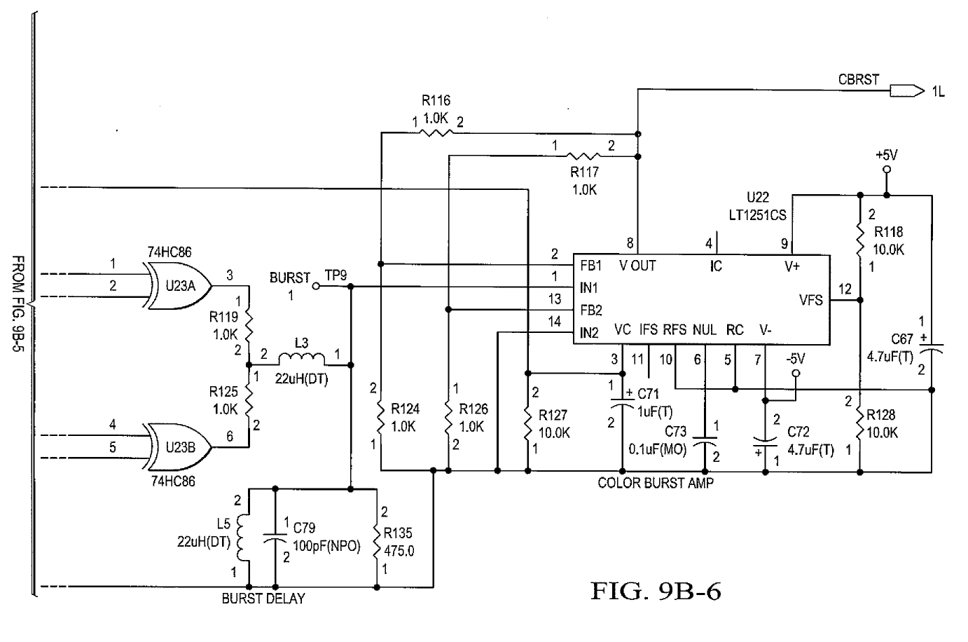

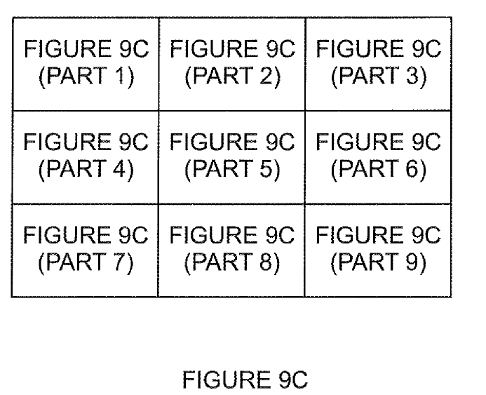

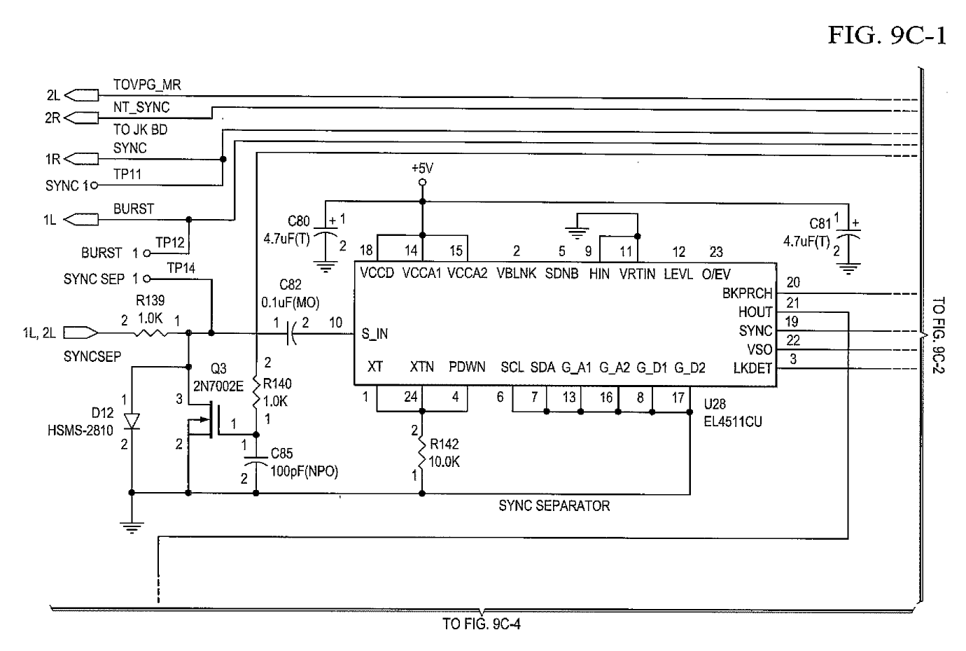

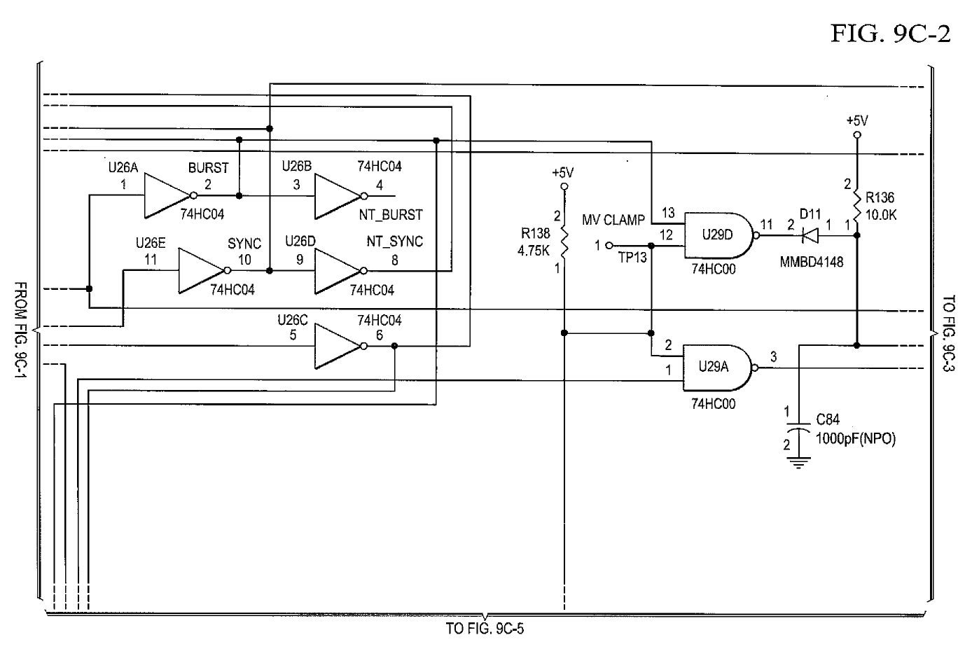

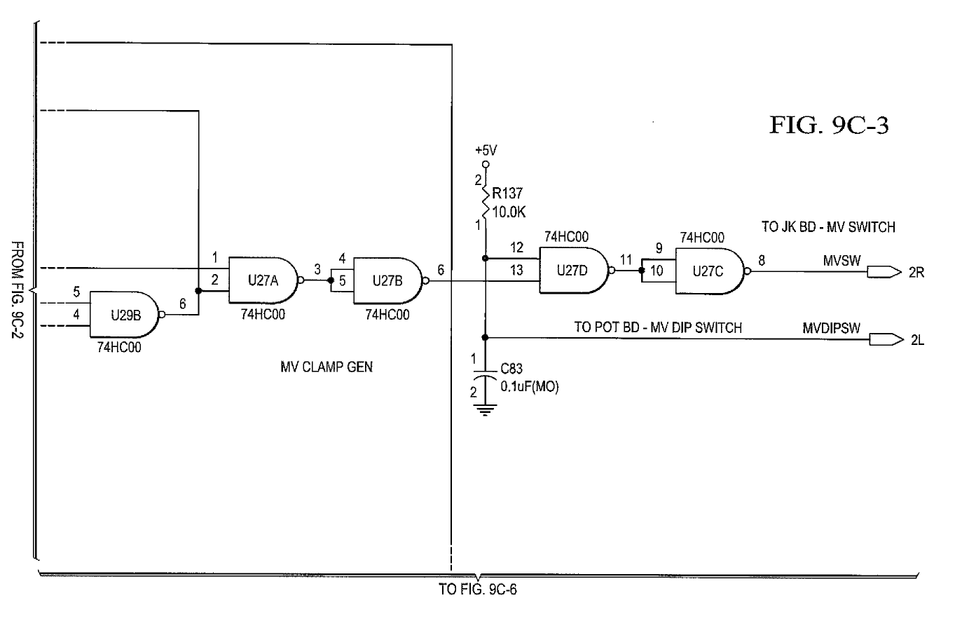

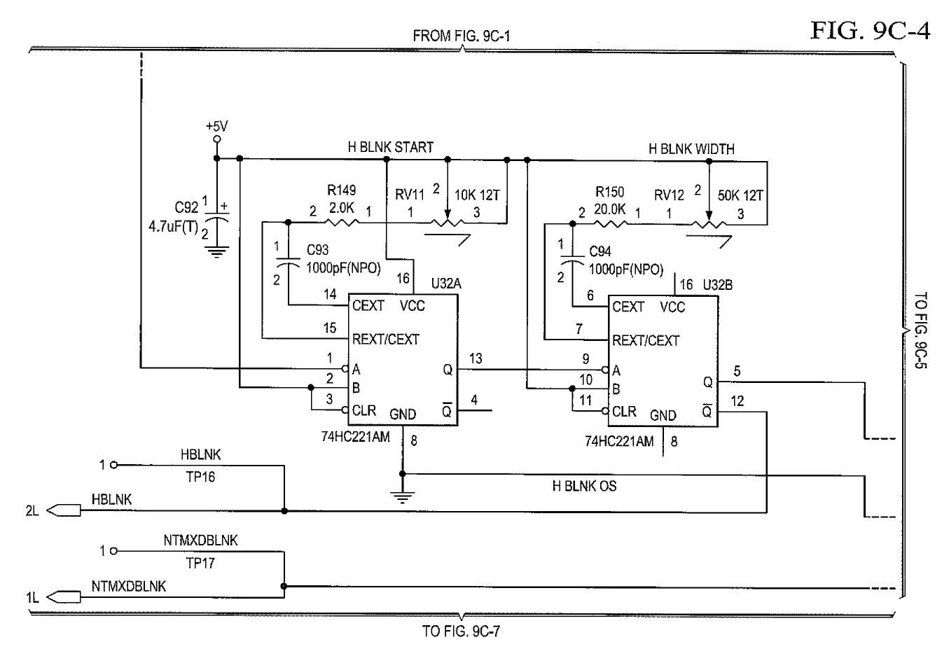

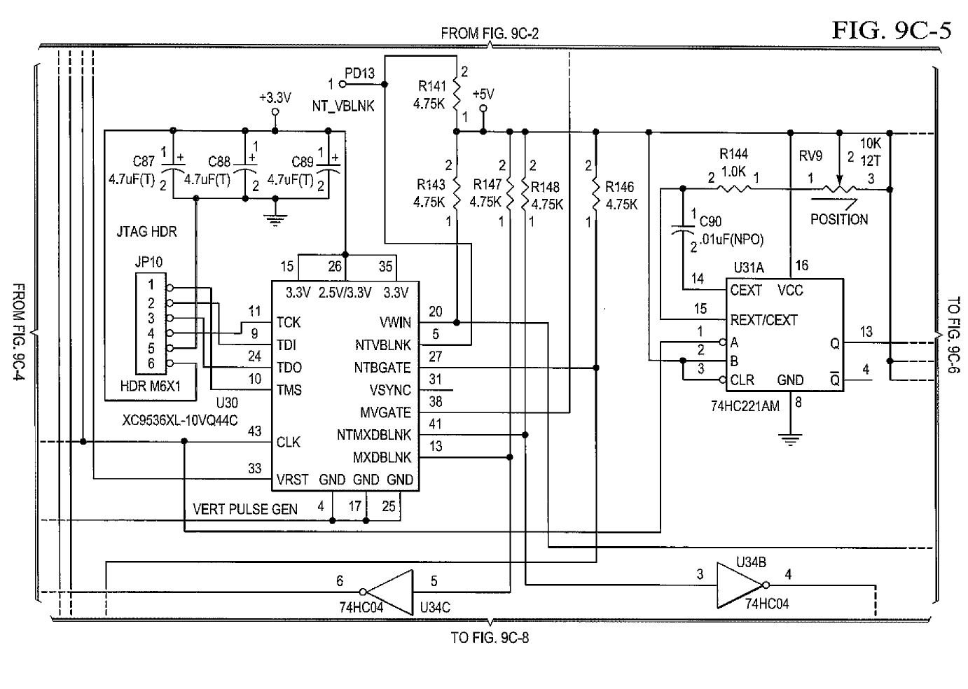

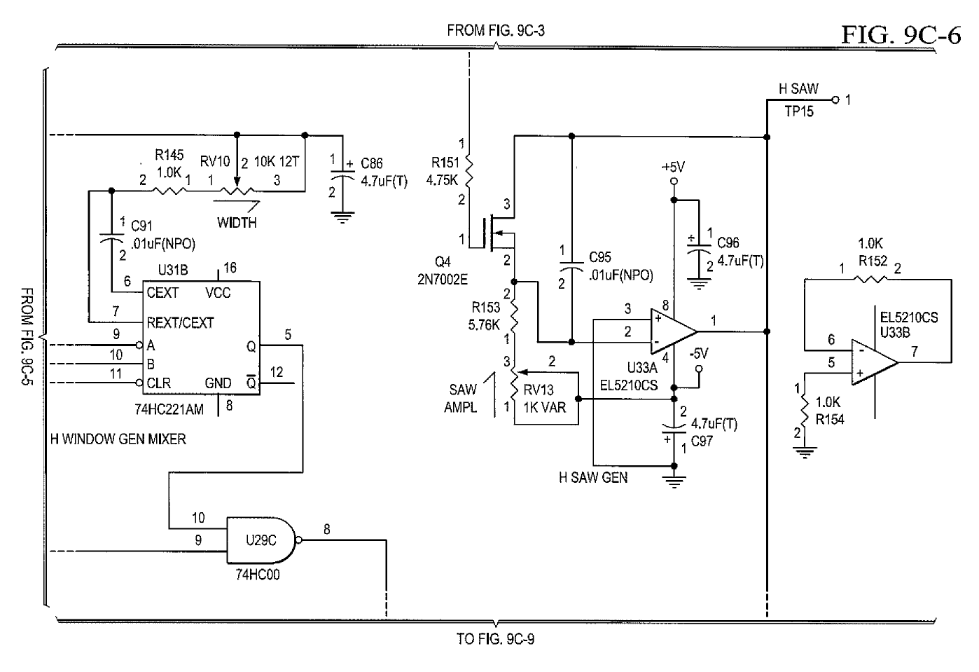

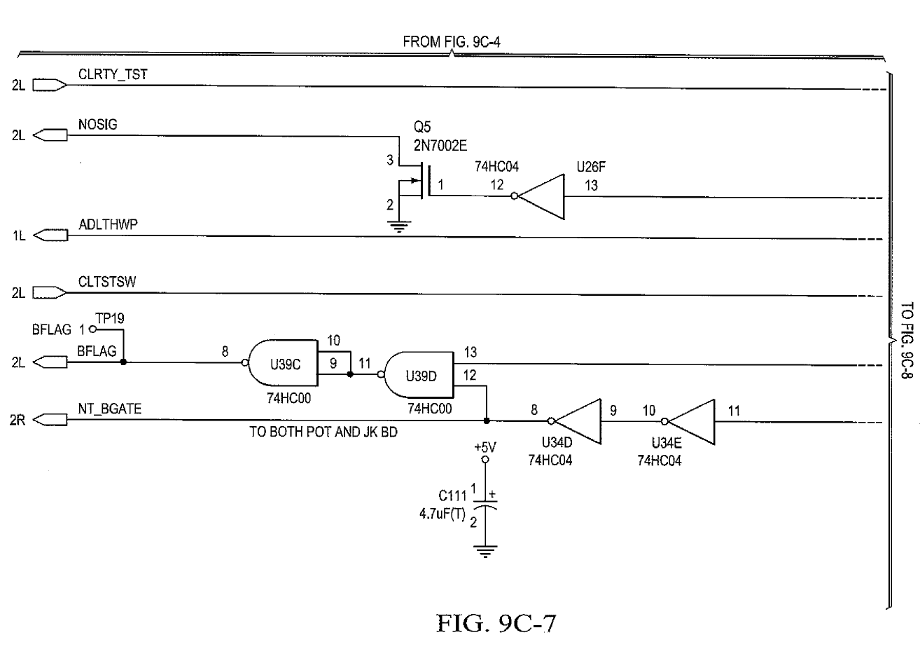

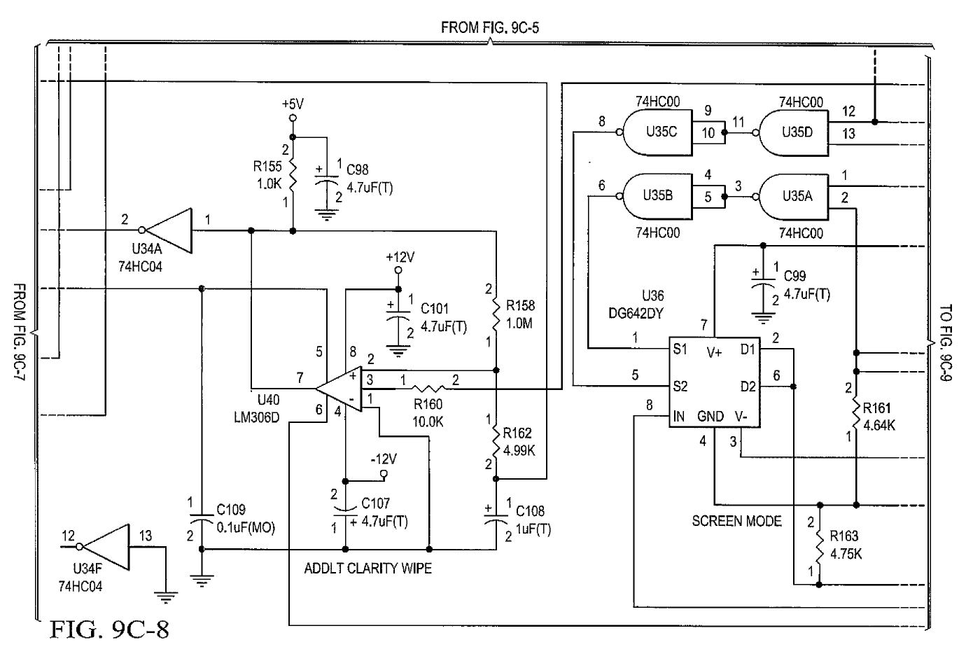

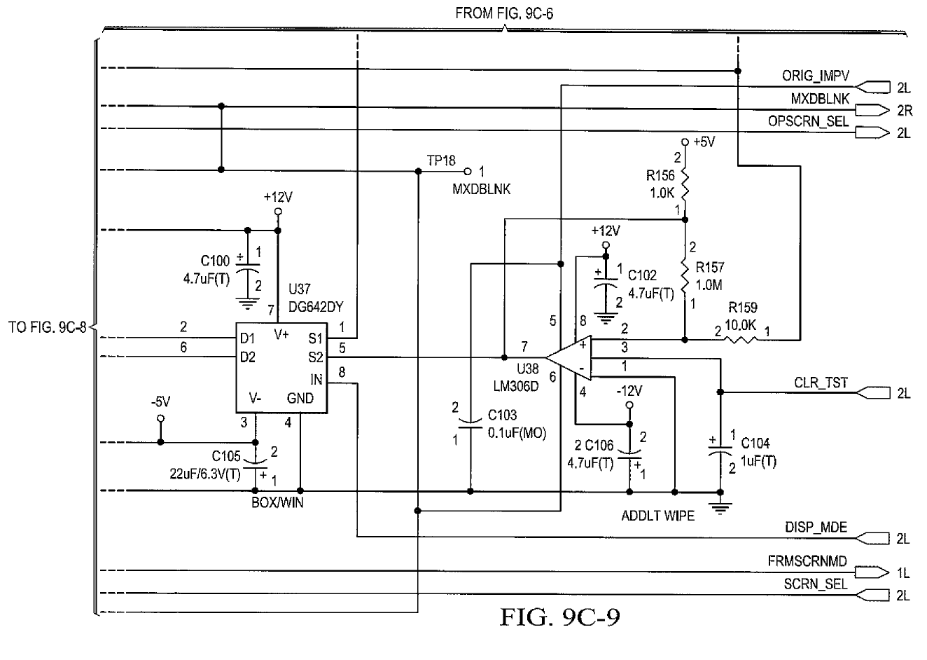

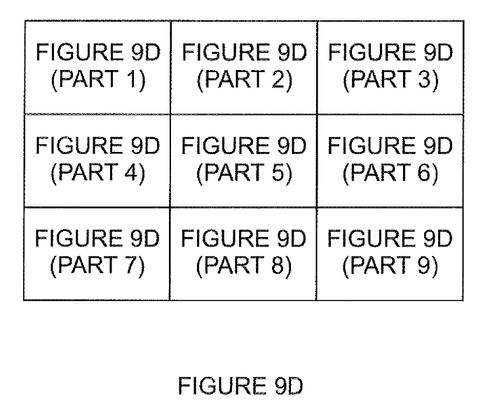

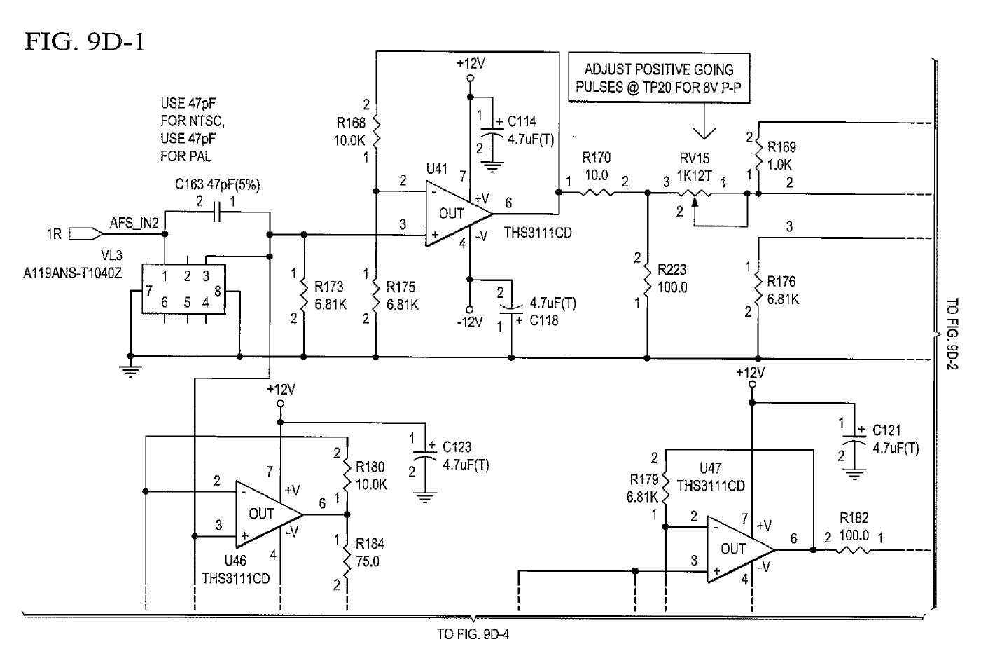

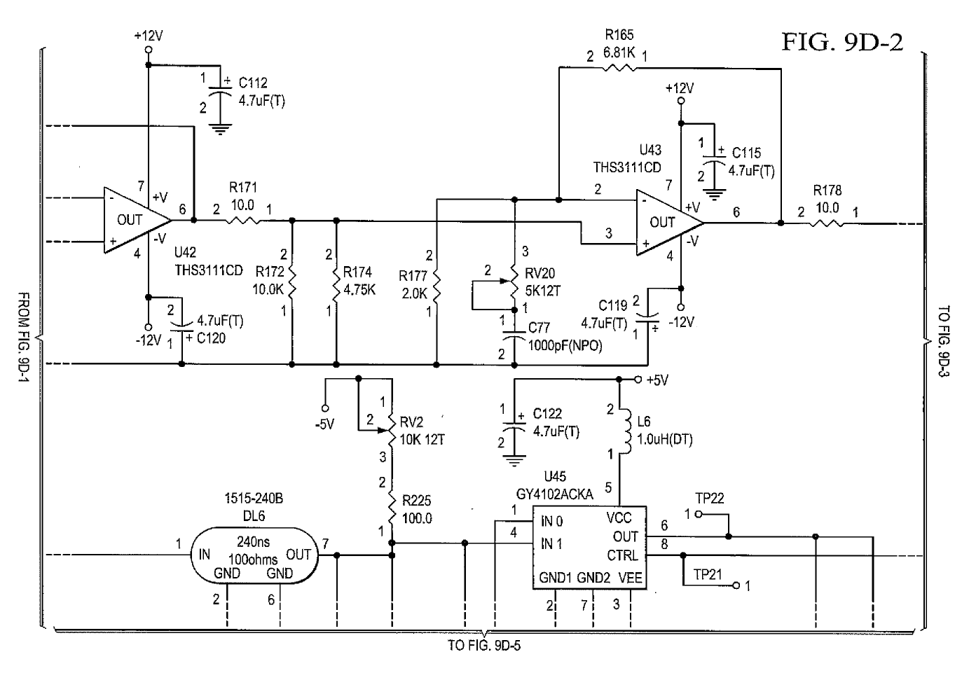

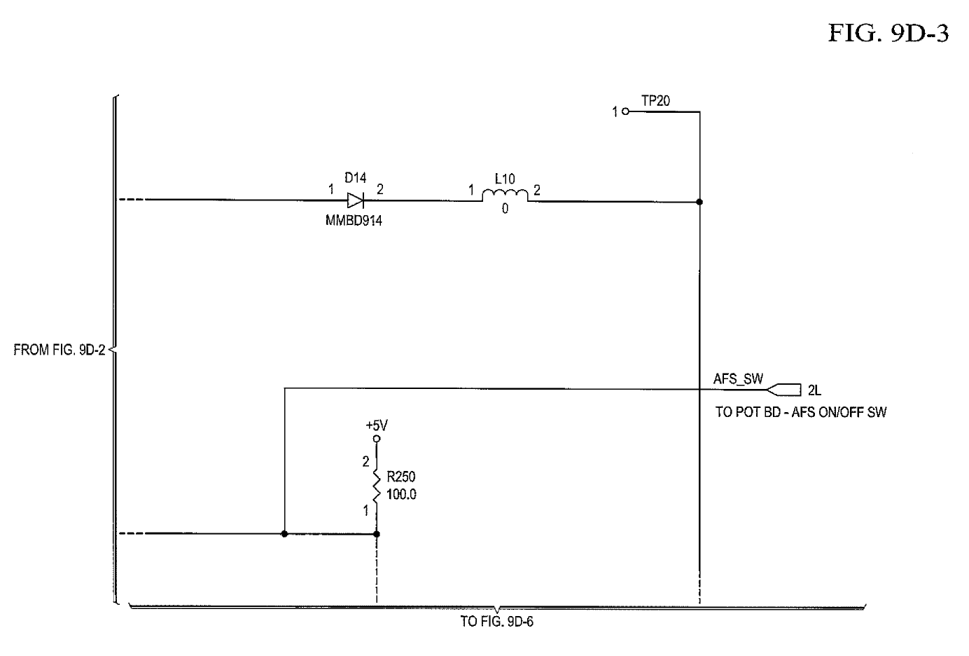

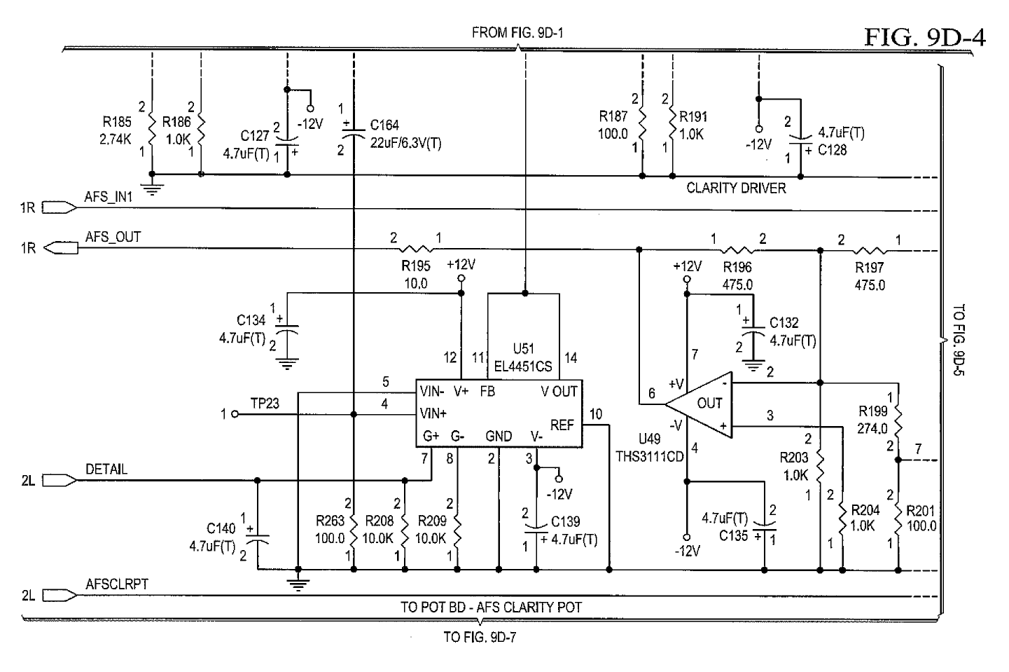

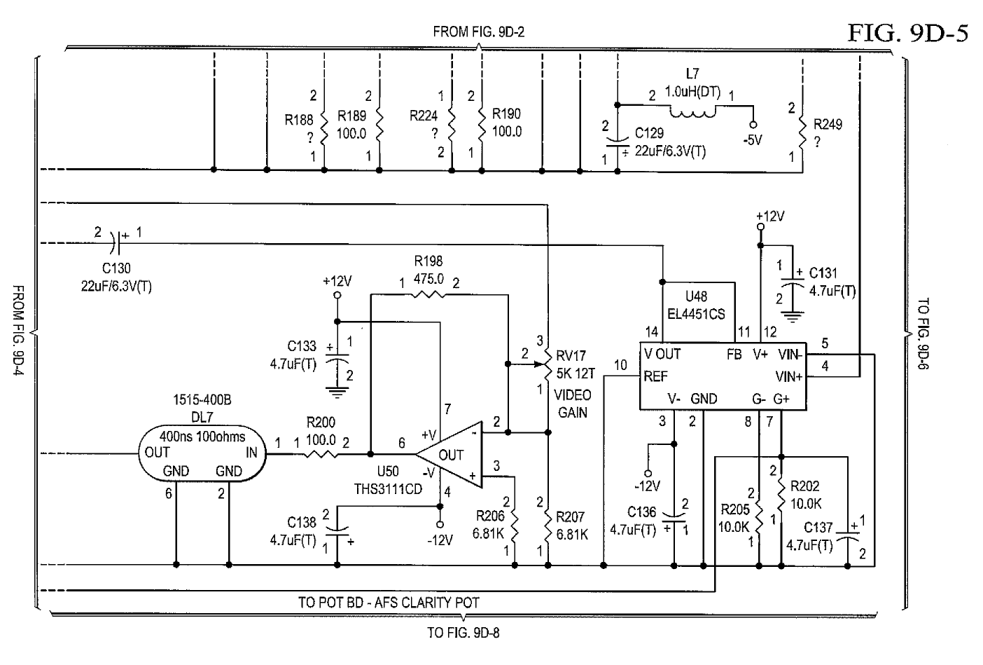

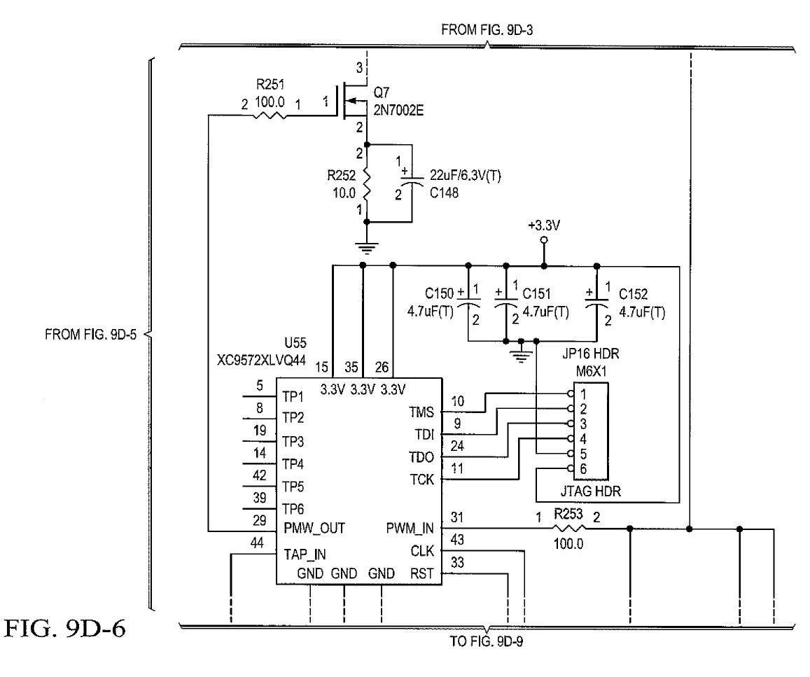

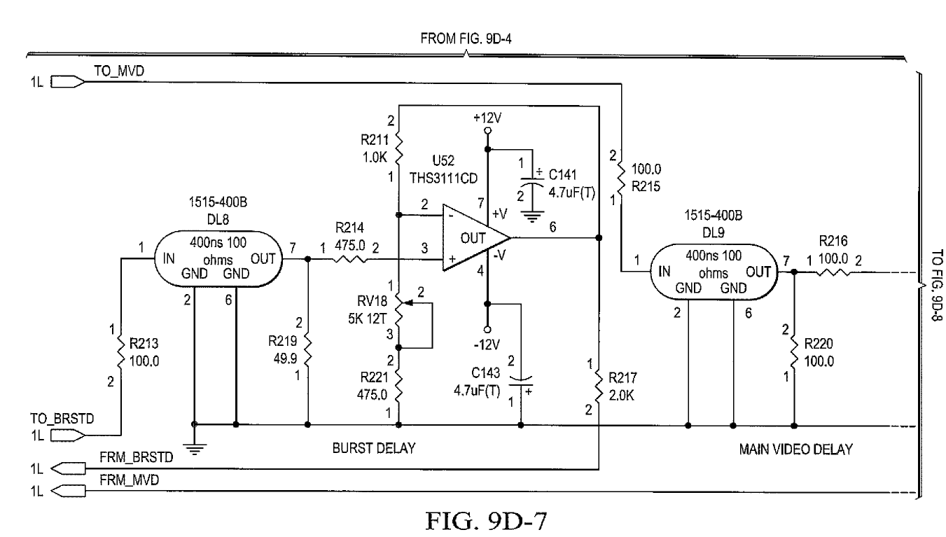

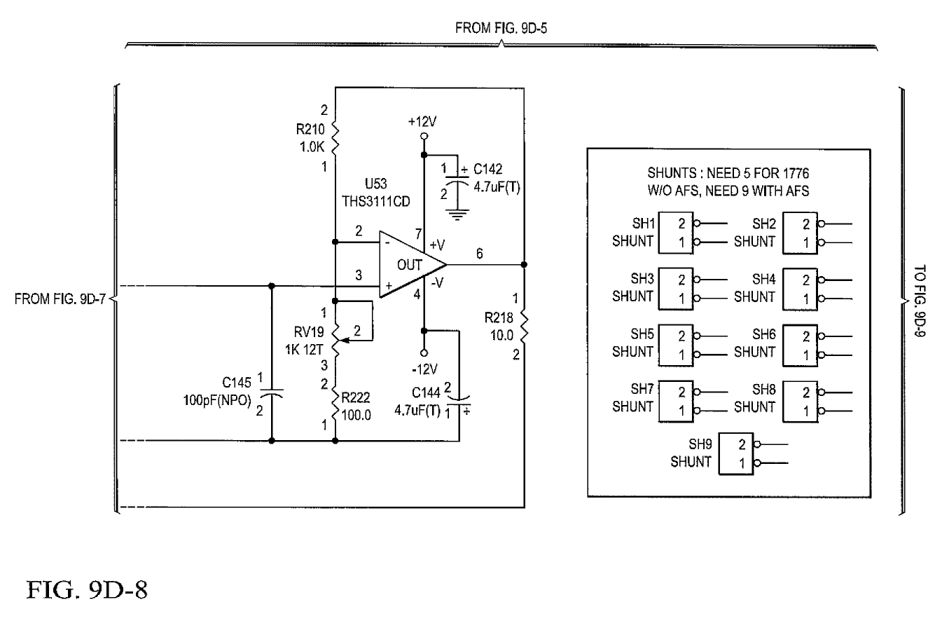

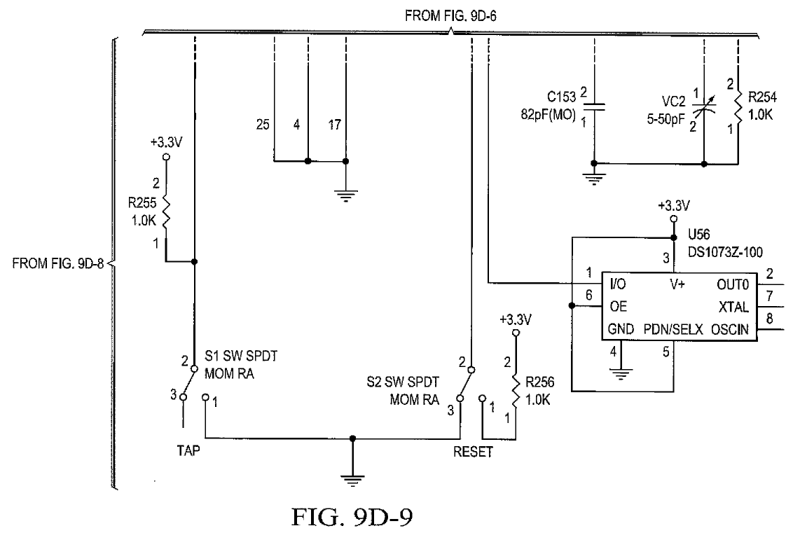

Additionally, a flashlight function can be applied to the luma signal. The luma path signals output from the luma/chroma separator 206 are processed by a flashlight circuit 226, discussed in further detail herein below with respect to FIGS. 6 and 9A-9D. The output from the flashlight circuit 226 is input into the luma delay amplifier 222 and combined with the output of amp circuit 220. The flashlight circuit 226 drives the delay luma amplifier 222. The flashlight circuit 226 modifies the luma signal by either raising or lowering the voltage level on a particular portion of the video. Accordingly, an output from the gamma amplifier may include the flashlight signals (e.g., output from the flashlight circuit 226) and gamma signals that modify the luma signals only.

Further, a black reference (also referred to as a pedestal) is applied at the output of the gamma amplifier 224. A black improve circuit 228 can include one or more black clip amplifiers and one or more black adjust amplifier. The black improve circuit 228 can provides a signal for a black reference that is combined with the luma signal at the output of the gamma amplifier 224. The black improve circuit 228 is controlled by a DC input that modifies black levels. The pedestal can be lowered from ‘7.5 IRE’ to ‘0 IRE’, or even down to ‘−2 IRE.’ The bottom of sync to top peak of amplitude is 100 IRE, wherein the signal is divided into one-hundred parts, each part equaling one (1) IRE. A level of 7.5 IRE indicates 92.5% blackness can be achieved. The black improve circuit 228 is configured to adjust the black reference from ‘7.5 IRE’ to ‘0 IRE’ or ‘−2 IRE’. Accordingly, the black improve circuit 228 can adjust the black to at least 100% black. Therefore, the black improve circuit 228 can improve contrast by making the blacks “blacker” than grey.

The blanking clamp 218 mixes the luma signal and chroma signal. The output of the blanking clamp 218 is a combined Y-C signal that includes luma and chroma signals that have been enhanced by the respective paths and passed through a high speed video switch.

An additive light function can be applied to the re-combined Y-C signal output from the blanking clamp 218. An additive light amplifier 232 receives an output from the blanking clamp 218. The additive light amplifier 232 can be DC controlled. As such, the additive light amplifier 232 can include or be coupled to a control that applies a DC voltage to vary the gain of the additive light amplifier 232. Therefore a potentiometer may not be required to vary the gain. Since the Y-C signal does not include synchronization information (e.g., running a non-composite signal), the gain of the chroma amp 214 can be raised substantially (e.g., as high as the supply voltage) to improve signal-to-noise ratio without phase shifting (for example, without causing a shift in the true colors). Phase shift in the chroma can affect the actual color appearing on the display 120. The additive light amplifier 232 applies the additive light function that is designed to be able to increase an amplitude range of the NTSC encoded signal without affecting an amplitude of the synchronizing and color burst information, as well as any effects on the systems differential gain and phase. The increased amplitude range allows for a higher video level to be sent through the video device 100 by the segregation of the composite sync signals, both Vertical, Horizontal, and color burst. The output from the additive light amplifier 232 is an enhanced Y-C signal.

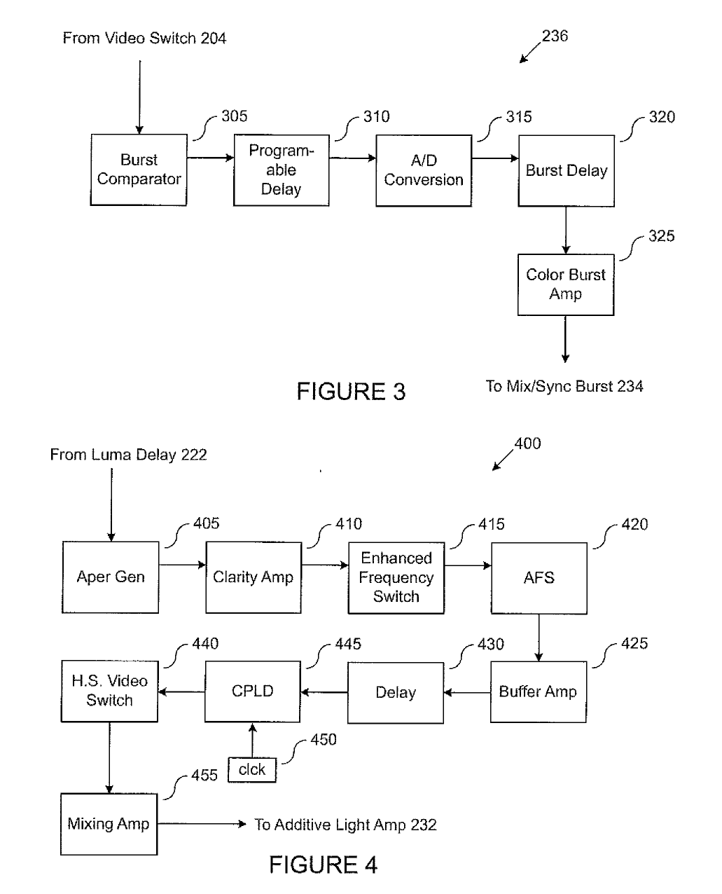

Thereafter, a mix/sync burst buffer amplifier 234 combines the enhanced Y-C signal output from the additive light amplifier 232 with the sync signal, which was separated by the video switch 204, and a regenerated color burst that was processed by Regeneration/Burst circuit 236. Regeneration/Burst amplifier 236 is discussed in further detail herein below with respect to FIG. 3. The mix/sync burst buffer amplifier 234 can include channels for the non-composite signals and the enhanced composite (i.e., recombined enhanced video signals) signals. The mix/sync burst buffer amplifier 234 can be coupled to the output interface 115 through one or more power amplifiers. For example, the mix/sync burst buffer amplifier 234 can include a luminance amplifier (not specifically illustrated) that contains the enhanced luminance signal and synchronization information. The mix/sync burst buffer amplifier 234 can also include a chrominance amplifier that contains the enhanced chrominance signal and synchronization information.

FIG. 3 illustrates a block diagram of the Regeneration/Burst amplifier 236 according to embodiments of the present disclosure. The embodiment of the Regeneration/Burst amplifier 236 shown in FIG. 3 is for illustration only. Other embodiments could be used without departing from the scope of this disclosure.

The Regeneration/Burst amplifier 236 receives the composite output, including the color burst signal information, from the video switch 204. The Regeneration/Burst amplifier 236 is capable of regenerating the burst in order to provide a better burst signal to the Mix/Sync Burst Amplifier 234 for use in the enhanced video signal. The Regeneration/Burst amplifier 236 reshapes the burst and provides for automatic line by line burst phase control. The Regeneration/Burst amplifier 236 improves an accuracy for the reprocessed color burst to have a correct phase relationship with the incoming video burst signal.

The burst signal is “keyed” by a burst-comparator amplifier 305. In the burst-comparator amplifier 305, a composite signal is analyzed. A fixed DC reference is applied to the burst-comparator amplifier 305. Using a burst flag (BFLAG) from a sync generator, the burst is keyed-in such that the non-flagged portions of the burst signal are eliminated or “keyed-out.” For example, the burst-comparator amplifier 305 can be gated by the BFLAG to respond only during color burst time. The output of the burst-comparator amplifier 305 can be a Complementary Metal-Oxide-Semiconductor (CMOS) logic level burst signal.

The burst-comparator amplifier 305 outputs the signal to a programmable delay line 310. The programmable delay line 310 is configured to correct a burst timing to match the main video and additive light channel time delays. Delay changes are synchronized horizontally by applying horizontal blanking to an address enable input. The programmable delay line 310 can be a four-hundred nano-second (400 ns) delay line. The nominal digitally selected color burst phase delay range can be greater than 360° at 3.58 MHz in two-hundred fifty-six (256) steps of 1.5°.

The output of the programmable delay line 310 is input into an Analog to Digital (A/D) converter 315. The A/D converter 315 digitizes the burst signal output from the programmable delay line 310. The burst phase control setting conversion occurs during VSYNC time. A square wave burst output is applied to a number of XOR gate inputs and a logic level selection is applied to another of the XOR gate inputs via a coarse phase switch that allows 0° or 180° coarse burst phase selection.

The digitized burst signal output from A/D converter 315 is delayed by Burst delay 320 for timing purposes. The Burst delay 320 can be a 100 ns delay. Thereafter, the burst signal output from the Burst delay 320 is amplified by Color Burst Amp 325. The Color Burst amp 325 is control by a DC gain control. Using the DC gain control, the color burst amp 325 is configured to raise or lower the gain or amplitude of the burst signal. The color burst amp 325 further includes a phase control configured to correct a phase of the burst signal. Thereafter, the output of the color burst amp 325 is recombined with the additive light signal, from the additive light amp 232, at the mix/sync burst 234 (for example, on the output of the buffer amplifier on the output of the additive light signal).

FIG. 4 illustrates a block diagram for an image enhancement circuit according to embodiments of the present disclosure. The embodiment of the image enhancement circuit 400 shown in FIG. 4 is for illustration only. Other embodiments could be used without departing from the scope of this disclosure.

In some embodiments, the video processor 110 includes an Image Enhancement Circuit (IEC) 400 (also referred to as an Image Clarity Circuit). The IEC 400 can improve a resolution of a video image displayed on display 120. The IEC 400 can provide additional details that were lost when the amplitude of the detail of the scanning beam of a Cathode-Ray Tube (CRT) fails to identify (e.g., pick-up) this detail information. The IEC 400 can enhance the high frequencies of the video signal from one and a half megahertz (1.5 MHz) and up. For example, the high frequencies can be amplified by twelve decibels (12 dB) over a normal signal level.

The IEC 400 receives the luma signal from the luma delay 222 via an aperture generator 405. The aperture generator 405 can include a delay line equalizer. The delay line equalizer can correct for phase differences. The output of the aperture generator 405 drives a Clarity Amp 410.

The clarity amp 410 drives an enhanced frequency switch 415. The enhanced frequency switch 415 can be an enhanced frequency diode network configured to invert a negative going transition.

The enhanced frequency switch drives an Automatic Frequency Suppressor (AFS) 420. The AFS 420 can be used in conjunction with other functions of the video processor 110, such as, but not limited to, flashlight, additive light, high-knee gamma correction, to improve video image performance. The AFS 420 is configured to enable amplify and delay transitions in the signals. The output of the AFS 420 is processed through buffer amp 425 and delay 430. The AFS 420, buffer amp 425 and delay 430 can enhance an image for sharper clarity by eliminating a halo effect that can occur when increasing the frequency response of the high frequency information in the video image. The AFS 420, buffer amp 425 and delay 430 eliminate the halo effect by suppressing unwanted transitions in the video signal which cause the halo effect.

For example, looking at an image, a white ring may appear around an object (such as a person's head). At the white ring (e.g., a halo), a high transition is apparent moving from the white ring to the person's head, where there is a lot of detail present, and then there is another transition. Along the person's head, the frequency is low. Therefore, the AFS 420, buffer amp 425 and delay 430 suppress the high transitions.

The output of the AFS 420, buffer amp 425 and delay 430 is input to a high speed video switch 440. The input to the high speed video switch 440 is triggered by a signal from a Computer Programmable Logic Device (CPLD) Off-Pulse generator 445. The CPLD 445 is driven by a 60 Mhz clock 450. The CPLD 445 is triggered by the transitions in the video. The CPLD 445 can turn off the video for a period of 500 ns to 1 micro second, and then the CPLD turns the video back on. The output of the high speed video switch 440 is input to a mixing amplifier 455 where it is mixed with the luminance prior to the additive light amplifier 232.

FIG. 5 illustrates a block diagram for a main video channel according to embodiments of the present disclosure. The embodiment of the main video channel 500 shown in FIG. 5 is for illustration only. Other embodiments could be used without departing from the scope of this disclosure.

In some embodiments, the video processor 110 includes a main video channel 500. The main video channel 500 carries the original composite video signal. For example, the main video channel 500 can carry the original NTSC video signal. The main video channel 500 can include no additional signal processing other than amplification and luminance and chrominance timing delay. The main video channel 500 can provide a representation of the input video signal in order to compare the enhanced video signal and the original video signal.

The main video channel 500 can be coupled to the output interface 115. The output interface 115 can be configured to provide a signal from the main video channel 500 signal and the enhanced video signal to the display 120. Thereafter, the display 120 can provide two images simultaneously. The first image can correspond to the enhanced video signal and the second image can correspond to a representation of the original video signal as received via the main video channel 500.

The main video channel 500 receives a non-processed luma signal from the luma amp in the luma amp/delay circuit 220. The main video channel 500 also receives a non-processed chroma signal from the amp and delay line in the Chroma amp/delay circuit 210. The luma signal from luma amp 220 and chroma signal from chroma amp 210 are combined and amplified by the main video amp 505. The output from the main video amp 505 is processed through output amp 510. The output from the output amp 510 is fed to a wipe circuit 515. The wipe circuit 515 also receives signals from the video processor that have been processed through the additive light amp 232 (hereinafter referred to as the additive light channel 520). Thereafter, the wipe circuit 515 can output the signal received from the output amp 510, the signal received from additive light channel 520, or both.

FIG. 6 illustrates a method for video enhancement according to embodiments of the present disclosure. The embodiment of the video enhancement process 600 shown in FIG. 6 is for illustration only. Other embodiments could be used without departing from the scope of this disclosure.

The video enhancement process 600 accepts NTSC composite encoded or YC video input signals. The video enhancement process 600 is configured to reprocess the video signal, replace the timing information and provide a process for improving the visual acuity of the video image. The video enhancement process can output a composite encoded source terminated NTSC signal; a composite encoded original input signal; two luminance source terminated signals; two chroma source terminated signals; and one composite source terminated monochrome signal.

The video enhancement process can include five main processing sections that include: video signal processing; chrominance processing; color burst signal processing; horizontal sync and vertical sync processing and timing; and test wipes and switching functions.

In step 602, a video signal is received. The video signal includes a composite signal that includes Color, Video, Blank and Sync (CVBS) components. The composite video signal is a composite of three source signals called Y, C with sync pulses. The video signal can be an encoded NTSC signal.

In step 604, the video signal is separated into separate paths. The synchronization (sync) information and color burst are removed from the composite video signal to form a non-composite video signal. Thereafter, high and low pass filters are applied separately to the non-composite signal in order to isolate luminance signals and chrominance signals in separate paths.

In step 608, the chrominance signals are amplified, delayed and phase shifted. The chrominance signals can undergo a phase shift of three-hundred sixty degrees (360°). Therefore, the phase of the colors are shifted to enhance information and detail for better viewing on the display 120. The chrominance signals are amplified under the control of a DC gain control. Since the chroma signal does not include synchronization information (e.g., running a non-composite signal), the gain of the chrominance signals can be raised substantially without suffering from the effect of clipping or compression.

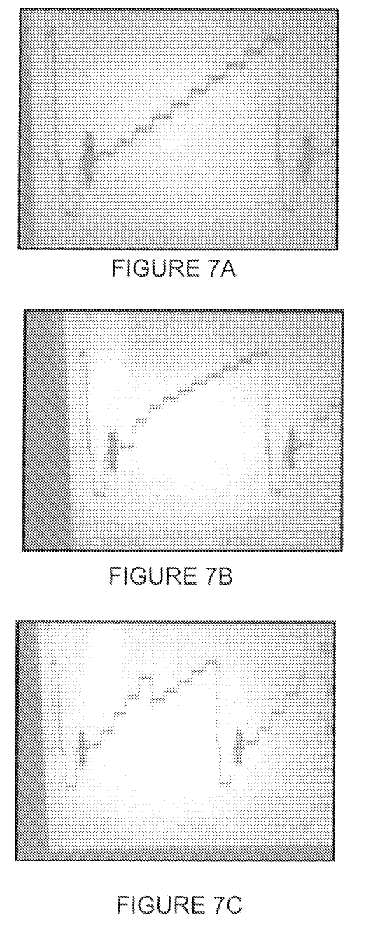

The luminance signals are fed (output or routed) along at least one of two paths. In step 610, a first path is amplified, delayed and, thereafter, a gamma correction function is applied. The gamma correction function can change the transfer function of the video signal (for example, the slope of the signal or signal linearity). The gamma correction function performed is a modified “high-knee” gamma function. The high-knee gamma correction function can change the transfer function of the video signal, such as, for example, a slope of the signal or signal linearity. This converts to the light intensity or voltage level at some voltage points in the video signal which relates to brightness on the TV Monitor. This signal linearity can be measured by applying the standard 10 step Stair-step signal (illustrated in FIGS. 7A-7C) to the input of the system. Each step represents a discrete voltage level (TV monitor brightness) during horizontal scanning time. Therefore any non-linear amplification (differential gain) of the video signal is easily observed, such as, but not limited to, Black Compression, White Compression.

In step 614, a black reference signal is adjusted and combined with the gamma corrected signals. The adjusted black reference signal are varied from ‘7.5 IRE’ to ‘−2 IRE.’

In step 612, a second path of the luminance signals is processed by a flashlight function. The flashlight function (Black Expansion) can raise the brightness level of certain portions of the video scene such as, for example, low light levels. Black Expansion differs from Gamma by threshold selectively expanding the Video amplitude in certain portions of the video scene, (zero to 50 IRE) by an adjustable amount of gain, while not affecting the peak white amplitude. Luminance signals are fed into a BLACK Expand comparator. A THRESH control sets the video level at which the expansion window occurs. The output is applied to an EXPAND RATIO control and diode coupled to the inverting input of a DEL LUMA AMP. An EXPAND RATIO control increases the signal amplitude, in an amount determined by a predetermined setting, only in the window. The BLK EXPND switch can provide glitch free vertical interval selection of the BLACK EXPANSION function. This feature is desirable when viewing low level video scenes, containing signal information in the black region which are not visible on a TV monitor or computer screen. The flashlight signals are combined with the first path prior to gamma correction.

In step 616, the outputs from the chrominance path and the luminance path are mixed. Thereafter, an additive light amplification function is performed on the mixed luminance-chrominance signals. The additive light function can increase the amplitude range of the NTSC encoded video signal without effecting the amplitude of the Synchronizing, and Color Burst information as well as any effect on the systems Differential Gain and Phase. The increased amplitude range allows for a higher video level to be sent thorough the system and is accomplished, in part, by the elimination of the composite sync signals, both Vertical, Horizontal and Color Burst. The NTSC encoded video signal is there by treated as a non composite video signal for amplification and signal processing purposes.

In step 618, the color burst information is regenerated by keying a burst signal. Using a burst flag from a sync generator, the burst is keyed-in such that the non-flagged portions of the burst signal are eliminated or “keyed-out.” The color burst is separated from the incoming video signal, and is applied to the input of the burst processing channel. The color burst process steps reshape the burst and provide for automatic line by line burst phase control. The color burst process steps insure the reprocess color burst always has the correct phase relationship, with the incoming video burst signal.

In step 620, the sync information, regenerated burst information and enhanced luminance-chrominance signals output from the additive light amplifier are mixed. The output of the mixing, also referred to as the output of the additive light channel, is output to a wipe control in step 622.

In step 622, a main video channel outputs a video signal corresponding to the original video imaged received in step 602. The main video channel carries the original NTSC video signal with no additional signal processing other than amplification and Luminance and Chroma timing delay. Therefore, when observed at the systems output, the main video channel provides a true representation of the input video signal.

In step 624, wipe control outputs the output from the additive light channel, the output of the main video channel, or both. The display is configured to display one or both of the video signals received from the wipe control.

FIGS. 7A-7C illustrate oscilloscope images for Stair-step signals according to embodiments of the present disclosure. The embodiments of the Stair-step signals shown in FIG. 7A-7C are for illustration only. Other embodiments could be used without departing from the scope of this disclosure.

The scope photo illustrated in FIG. 7A, shows a 1 volt peak to peak Stairstep Generator signal without any Gamma or Flashlight corrections in the system. This is the standard stair step signal which checks for linearity through a video system. It is noted that the scope graticule represents 200 milli-volts per division and the first step is set on Black. Each step represents a discrete voltage or illumination, or grey tone, in the video scene over the entire raster scan of one field of interlaced video.

The scope photo illustrated in FIG. 7B, shows the same Stair Step signal as in illustrated in FIG. 7A, with the Gamma Correction control of gamma amp 224 set for maximum. Here the Gamma correction signal is parabolic in shape, illustrating the high-knee gamma correction. The first stair step of the signal remains at black and step 10 is still at one volt, even though the second step is a 200 milli-volts above the first stair-step. This capability aids in the shadow illumination capabilities along with the flashlight circuitry.

The scope photo illustrated in FIG. 7C, shows the same Stairstep signal as in illustrated in FIG. 7A, with the Flashlight Correction control at maximum. Here, the fifth step is 400 mil-volts above the sixth step, which is demonstrating the operation of flashlight circuit 226 and the selective gain characteristics of video processor 110.

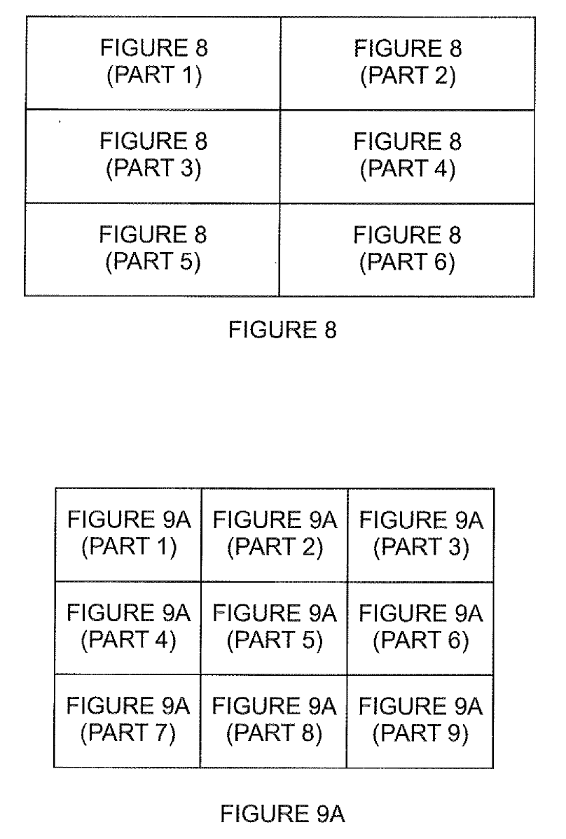

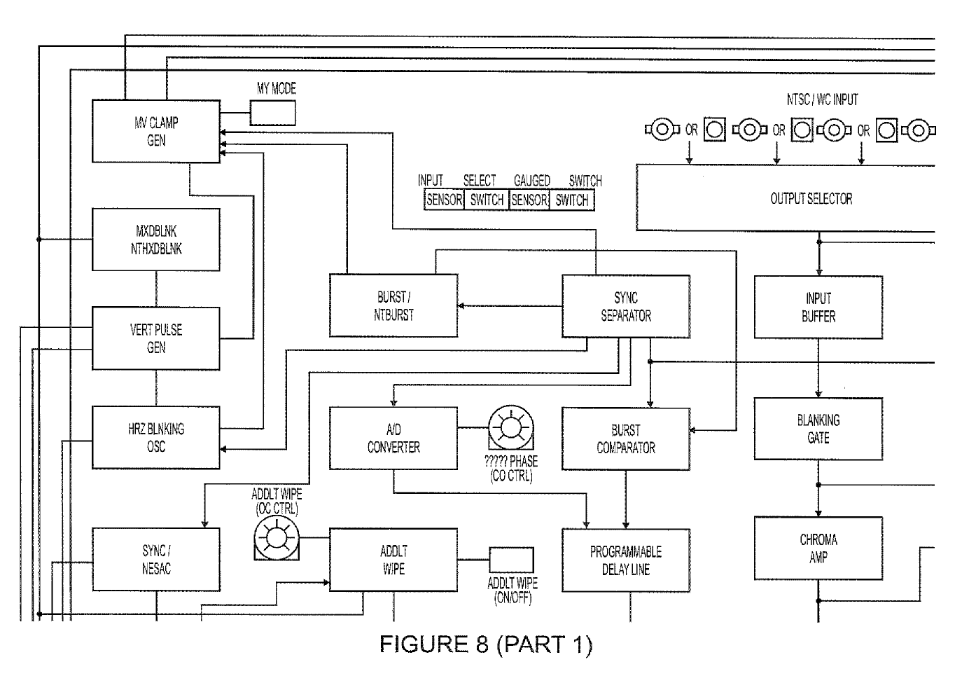

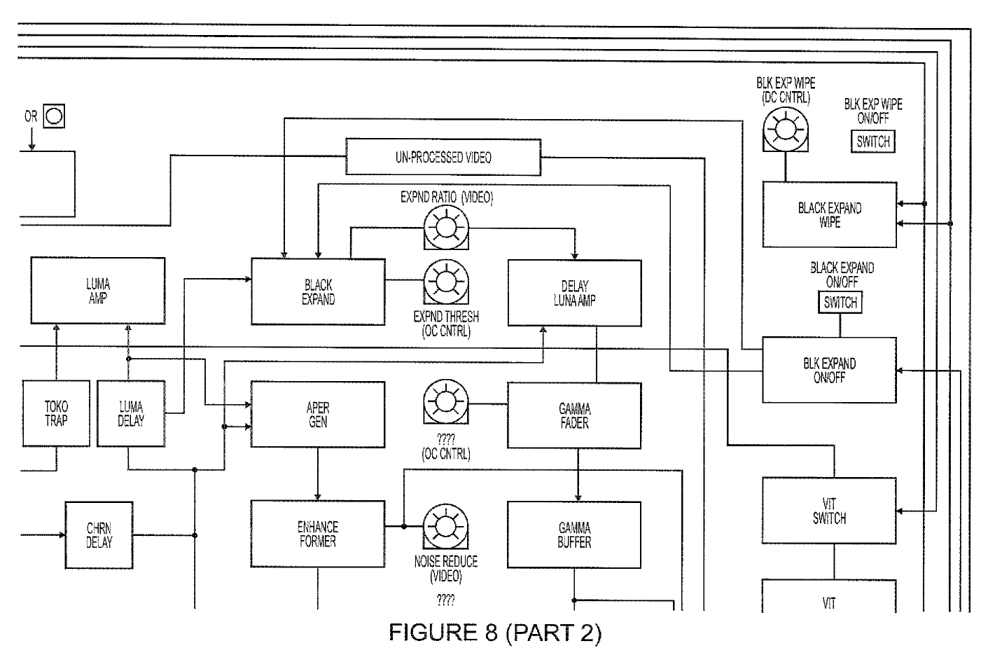

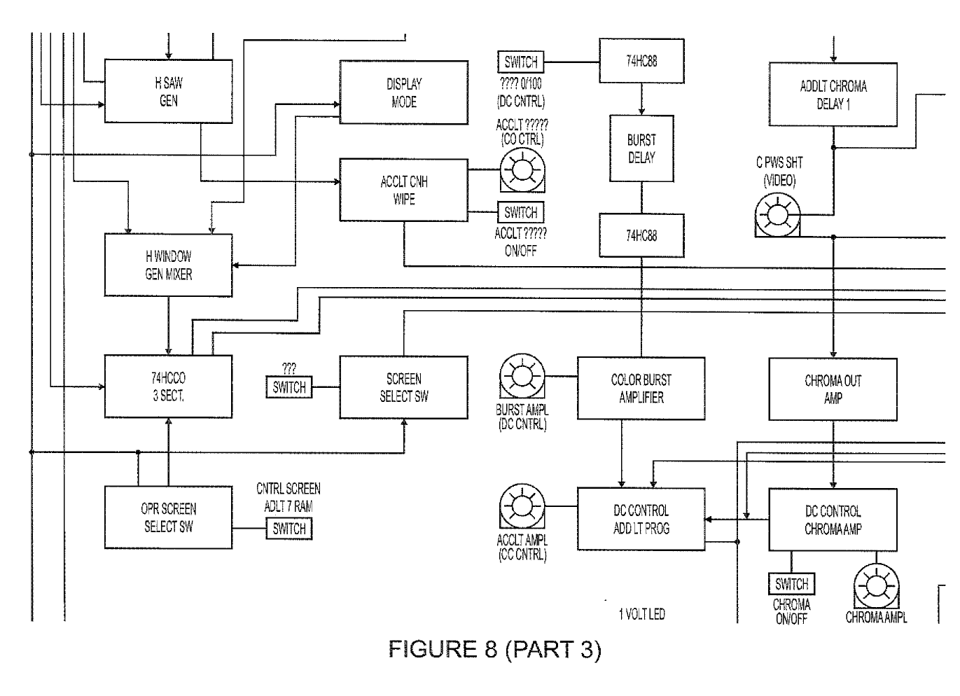

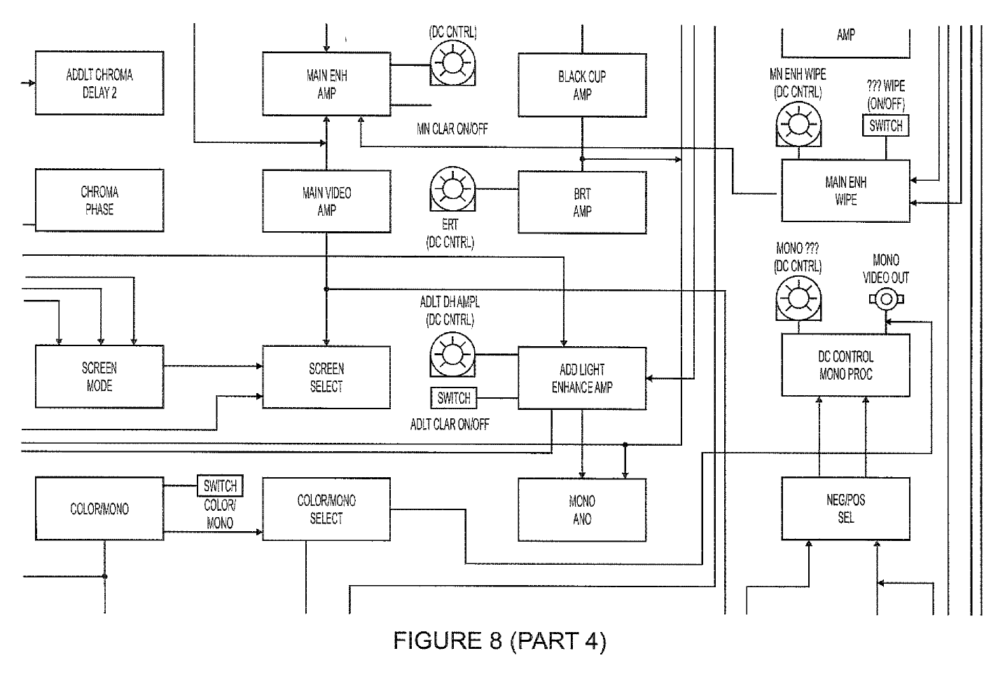

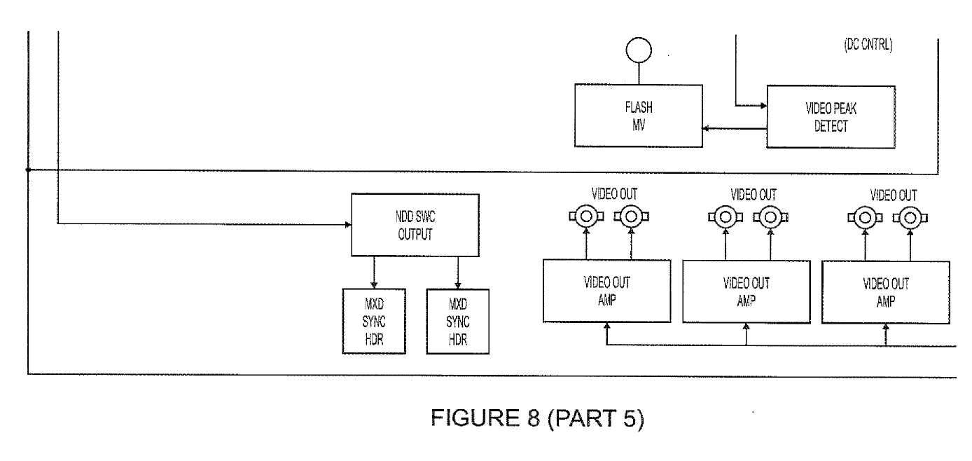

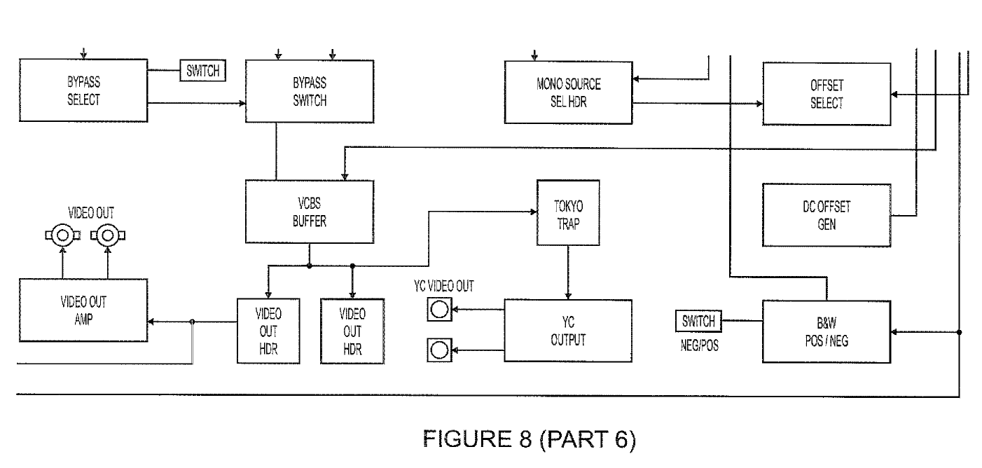

FIG. 8 illustrates another block diagram of the video processor 110 according to embodiments of the present disclosure. The embodiment of the video processor 110 shown in FIG. 8 is for illustration only. Other embodiments could be used without departing from the scope of this disclosure.

The video processor 110 illustrated in FIG. 8 includes a input buffer, blanking gate, chroma path, luma path, sync path, and color burst path. The video processor 100 further includes chroma amp, chroma delay, chroma phase shift, chroma output amp, luma amp, luma delay, gamma correction (gamma fade and gamma buffer), flashlight amp, black clip, main video amp, color burst comparator, programmable delay line, burst delay, burst amplifier, and a plurality of outputs.

The video processor 110 is capable of enhancing the video signal by eliminating a portion of the bandwidth occupied by macro-vision. By eliminating the portion of the bandwidth occupied by macro-vision, the video processor 110 is operable to improve a signal to noise ratio and increase bandwidth capacity.

FIGS. 9A-9D illustrate a schematic diagram of the video processor 110 according to embodiments of the present disclosure. The embodiment of the video processor 110 shown in FIGS. 9A-9D is for illustration only. Other embodiments could be used without departing from the scope of this disclosure.

A certain amount of the circuitry, has been included in the current electronics for demonstration purposes, in order to facilitate the understanding of the improved video image when compared to the original video image.

A bypass function, in the electronics, allows for the selected input video to be routed around the processing circuitry and be connected directly to the video output amplifier.

All operational mode switching is performed during the vertical interval, after the vertical sync time, which creates negligible disturbance to sync and no visible or interfering glitches in the output video signal. Trans-Impedance Amplifiers are utilized for all fixed gain video amplifiers in the unit. In addition, a Macrovision processing circuit is included, which may be programmed to remove or pass the copy prevention signals from the vertical blanking interval.

Overview of the Functions of the Channels of the Video Processor 110 are as Follows:

Additive light channel is for processing the non composite video to establish proper video level and proper signal timing, when mixed with the enhancing pulses from the clarity channel.

Clarity channel process the enhancing pulses (edge transitions) from the Additive light Clarity amplifier U11 and provides timing and control circuitry necessary to be mixed with the non composite video signal in the AFS additive light channel.

Pulse shaping channel and off pulse generation develop the necessary pulse information to perform the automatic frequency suppression in the enhanced video signal of the additive light channel.

Main Video channel establishes the proper luminance and Chroma timing for the main video when compared to the AFS additive light channel.

Burst Delay channel establishes proper burst phase for the main video and additive light channels.

Operation of the Additive Light Channel:

The composite (video and sync) NTSC video signal output from the Input Buffer amplifier U6/THS 3111 is applied to pin 1 of U6-LMH6570MA, the Blanking Gate. This amplifier eliminates both vertical and horizontal sync signals and the color burst at the output of the amplifier. U6 is a high speed two input video switch which is controlled by the composite blanking pulses (horizontal and vertical) applied to pin 2. When the positive going blanking pulses are applied to pin 2. The output of the amplifier can be switched to the amplifier input pin 4, which is grounded. Therefore the sync signals can be eliminated from the video during Vertical and Horizontal blanking periods, which leaves the video signal in the non-composite state at the amplifier output. The non-composite video signal is now split into to two paths, Luminance and Chrominance. The video processor 110 performs functions on these two signals. The functions can include, but are not limited to, Gamma correction, Flashlight. The Luminance and Chrominance can be recombined later to be controlled by the Additive Light Circuitry.

The non-composite Luminance and Chrominance signal, is recombined by the resistive network R37/R58/R59 at the input of U7 Blanking Clamper, where the signal is once again clamped to ground by the positive blanking pulses at pin 2 of the LMH6570 Blanking Clamp. The recombined non-composite output of U7 (Luminance and Chrominance, no Color Burst) is applied to the U18 Additive Light Amplifier, via R97/R109 voltage divider which sets the proper input levels U18 is a LT1251, 40 Mhz Video Fader and DC Gain Controlled Amplifier that eliminates the conventional resistive gain control type circuitry. Therefore, this eliminates any glitches in the video signal when the video gain in increased or decreased. This amplifier is configured to act as single channel amplifier. For example, where as fading can be performed from one channel with signal to the other channel without signal to control amplitude, by the application of 2.5 VDC to pin 3 of the LT1251. The signal amplification (additive light/signal energy) is controlled by the DC voltage that is applied to pin 3 of U18, by the Additive Light Control VR11, (front panel control) and the R/C network R8/R115 which acts as a voltage divider, so only 2.5 volts may be the maximum voltage to appear at pin 3. C57, lmf capacitor acts as a filter. As the DC voltage is applied to pin 3, the amount of video signal that appears in the output of the amplifier is controlled from zero to the maximum output voltage, set by feedback resistors R95/R110. The output of U18 pin 8, is then applied to U19 which acts as a buffer amp and where the sync and burst are recombined in the video signal via resistive network R92/R101.

Operation of Gamma

Luminance video from the appropriate tap of DL3 Luma Delay Line, is applied to the non-inverting input of U16 Black Expand Comparator AD790JR. AD 790JR can be a 45 ns precise voltage comparator. The Threshold Control, VR6, applies plus 5 VDC via resistor network R13/R86 to pin 4 of the comparator. The threshold control sets the video level at which the expansion window occurs. The U16 output is applied to a Quad 2 Input NAND Gate 74HCOO, U54A and the U54B, which allows the Black Expanded switch (in or out) to be operated glitch free, by switching in the Vertical Interval. The output of U54 is applied to the EXPAND RATIO CONTROL, RV5, and diode coupled to the inverting input of U13 DEL LUMA AMP. The Expand Ration Control increases the signal amplitude in an amount determined by the voltage applied to the comparator in the window provided by the comparator.

Operation Clarity Channel:

The negative enhancing transition pulses from the clarity buffer U21 are fed via JP3 pins 3&4 to the non inverting input of U41 and U46 pulse shape and clarity input buffer amplifiers, via Chroma trap VL3. The Chroma trap VL3 can limit 3.58 Mhz frequency information such that noise does not appear in the enhanced information of the clarity channel. The suppression of the 3.58 Mhz information can be performed such that edge noise does not appear in the video signal when the AFS in on.

U46 can be an operational amplifier and acts as a buffer gain amplifier for the enhanced transitions. The output of U46 is applied to the R/C network R184 and C164 which established the DC and AC signal level at the input to U51 (EL 4451) Detail Amplifier. The signal is then pass through the detail amplifier and applied to the non inverting input of U47 (3111) Clarity Delay Line Driver amplifier. The output of U47 is then applied the R182, a 100 ohm resistor which acts as the source impedance for delay line DL 6. DL 6 can be a 240 nano second delay line that sets the timing of the enhancing transitions to the video in the additive light channel and is terminated by R189 100 ohm resistor.

The signal then is applied to the input of U45 pin 4, which is a video switching amplifier GY 4102, which acts as the enhance On/Off switch when pulses are applied to pin 8. Therefore, RV variable resistor and the fixed resistor R225 allow for this adjustment. Pin 8 of U45 allows for the on/off pulses from the off pulse generator U55 to control whether or not the enhancement signals are present at the output of U55 at pin 6

The enhance transitions then can be provided to U48 enhance amplifier, whose gain is controlled by the clarity gain control on the front panel of the module. This amplifier determines the actual enhance level in the video signal at the output of the 1776.

Operation of the OFF-PULSE GEN:

The negative going enhancement transitions from U21 clarity buffer amplifier, via JP3 are applied to the input buffer amplifier U41/3111 operational amplifier non inverting input pin 3, via Chroma trap VL2. The Chroma trap can maintain the 3.58 Mhz Chroma information from creating noise problems in the subsequent pulse circuitry. R173 and R186 provide the Chroma trap termination and R168 and R175 set the fixed gain of U41.

The output signals of U41 are applied through R 170 to the resistive network R233, RV15 and R169 which is in the feedback circuit of U42 pulse gain amplifier. This network can provide the necessary gain characteristic for the amplifier. R176 provides a ground return for the non inverting input of the amplifier. The output of U42 is fed through R171 to the non inverting input of U43/3111 pulse trigger amplifier. The resistive network R165 and R177 set the fixed low frequency gain of the amplifier and the R/C combination RV20 and C77 provide the variable high frequency gain. This circuit is especially critical for setting high frequency triggering information to the off pulse generator U55. Improper setting of this control may appear as noise in edges of the color bar information. The resistive network R172 and R174 provide the required termination for U42 and input impedance for U43.

The output triggering pulses of U43 can be applied to the input of U55 pin 31, Off Pulse Generator, through diode D14, which acts as a clipper for unwanted base line information in the signal. The R/C combination of C153, VC2 and R254 provide the proper termination and signal symmetry of U43. R253 provides the source impedance to U55, a XC9572XLCQ44 programmable ASIC IC. U56 DS1073Z-100 provides the necessary 50 Mhz clock frequency for U55 to function.

The function of U55 can provide the necessary off pulses to U45 pin 8, via Q7 pulse inverter amplifier, which are proper in width and phase relationship to the enhancing pulses in the clarity channel that are to be turned off.

Since the triggering of U55 and subsequent output pulses that are generated by the enhancing signals, they have a direct relationship to what enhancing information is in the video signal. The triggering level at the input of U55 must be 2.5 volts p/p for off pulses to be generated. Therefore any enhance information in the video signal not at that triggering level will remain enhanced, where as enhanced levels equal to or greater than 2.5 volts at the input of U55 will not appear in the video output signal. Variable resistor RV15 in fed back loop of U42 establishes this level at the input of U55.

The pulse width from U55 and the resulting 5 volt positive output signal from Q7, polarity inverter pulse amplifier, which is applied to pin 8 of Q45, establishes the enhancing signals which are allowed at the output of Q 45. The trigger pulses at pin 8 are directly proportional to the horizontal scan duration less the width of the applied triggering pulses. This positive 5 volt signal which is applied to pin 8 of U45, switches the output from pin 1, which is terminated to ground through R190, to pin 4 of the GY 4102 input where the enhancing information is present from U47 via DL6.

U55 is programmed for a fix output pulse width of 500 nano seconds, plus the input pulse width, which equals the actual output pulse width applied to pin 8 of U45.

PwT=PwF+PwIn [Eqn. 1]

U55 may be programmed for any fixed pulse width desired. By programming U55 for a pulse width duration of less than 500 nano seconds, allows for higher frequency enhancement of the signals in the video if desired. This may create some undesirable hallo effects in some scenes of the video image.

The output of U45 is then fed to the Clarity Gain Amplifier U48/EL4451 pin 4, whose gain is control by varying the dc voltage applied to pin 7 by the clarity control on the front of the module.

The output signal of U48 pin 14 is applied through C130 to the non composite/enhancing mixing restive network R197/R203 at the inverting input pin 2 of U49.

Operation Main Video Channel:

The non composite main video signal is fed from J6 pin 3&4 to the Delay Line DL9, via a 100 ohm resistor R215, which acts as the source impedance for the delay line. The purpose of this delay line is so the Main Video signal has the proper phase relationship to the additive light video signal. The output of DL 9 is then applied to resistive network R220 and R216 in the input of U53 (3111) operational amplifier. R220 is the termination for DL9, which provides 400 nano seconds of delay for proper timing of the video signal to the additive light channel. The video signal is then applied to U53/3111 which has enough gain to off-set the insertion loss of the delay line DL9. R222 and RV 19, 1K ohm variable resistor & RV 210 allows for setting the gain of the main video channel to match exactly the level of the input video to the 1776 system. The output of U53 is fed to U14/GY4102 via JP6 pins 1&2 for final processing through the 1776.

Operation of the Burst Delay Channel:

The color burst from the output of U22 Color Burst Amplifier LT1251CS pin 8, via JP1 pin 1&2 is fed to DL 8 through R213, 100 ohm resistor which acts as the source impedance for the delay line. D/L 9 is a 400 nano second delay line which corrects burst timing to match the main video and additive light channel time delays. The output of the delay line, which is terminated by R 219/100 ohm resistor, is applied to U52/3111 operational amplifier through R214 which set the proper signal level to the non inverting input, pin 3. The resistive network R211, RV18 and R221 in the fed back loop of the amplifier allow for the adjustment of the burst level at the output pin 6. The output of U52 is then applied to the inverting input of U19/3111.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. An apparatus for use in a system capable of displaying video images, the apparatus comprising:
a video input configured to receive a composite video signal, the composite video signal comprising a luminance and a chrominance;
a video processor configured to separate the composite signal into separate luminance and chrominance paths, wherein the video processor is configured to perform video functions on the separate paths individually and combine the separate paths to produce an upgraded video image; and
a video output configured to receive the combined upgraded video image from the video processor and output the upgraded video image to a display.

2. The apparatus as set forth in claim 1, wherein at least one of the functions is an additive light function and wherein the video processor comprises an additive light circuit configured to perform the additive light function on a combined signal comprising at least two of the separate paths.

3. The apparatus as set forth in claim 1, wherein at least one of the functions is an high-knee gamma function comprising a high-knee in a parabolic curve and wherein the video processor comprises a high-knee amplifier configured to perform linear transition from the high-knee gamma function to a linear function one of the separate paths.

4. The apparatus as set forth in claim 1, the video processor comprising a flashlight circuit configured to perform a threshold selected video black expansion function on one of the separate paths.

5. The apparatus as set forth in claim 4, wherein said black expansion function adjusts a black reference black reference below 7.5 on the Institute of Radio Engineers (IRE) standard.

6. The apparatus as set forth in claim 1, the video processor comprising a burst circuit, the burst circuit configured to identify a burst flag in the composite signal, perform an analog-to-digital conversion on one of the paths and amplify the digitized path.

7. The apparatus as set forth in claim 1, further comprising a main video channel configured to output the upgraded video image and an uncorrected video image in the composite video signal.

8. The apparatus as set forth in claim 1, the video processor comprising:
an automatic frequency suppressor circuit;
an enhanced frequency switch; and
a plurality of delay paths.

9. A video display system comprising:
a display;
a video input configured to receive a composite video signal, the composite video signal comprising a luminance and a chrominance;
a video processor configured to separate the composite signal into separate luminance and chrominance paths, wherein the video processor is configured to perform video functions on the separate paths individually and combine the separate paths to produce an upgraded video image; and
a video output configured to receive the combined upgraded video imaged from the video processor and output the upgraded video image to the display.

10. The system as set forth in claim 9, wherein at least one of the functions is an additive light function and wherein the video processor comprises an additive light circuit configured to perform the additive light function on a combined signal comprising at least two of the separate paths.

11. The system as set forth in claim 9, wherein at least one of the functions is an high-knee gamma function comprising a high-knee in a parabolic curve and wherein the video processor comprises a high-knee amplifier configured to perform the linear transition from the high-knee gamma function to a linear function high-knee gamma function on one of the separate paths.

12. The system as set forth in claim 9, the video processor comprising a flashlight circuit configured to perform a threshold selected video black expansion function on one of the separate paths.

13. The system as set forth in claim 12, wherein said black expansion function adjusts a black reference black reference below 7.5 on the Institute of Radio Engineers (IRE) standard.

14. The system as set forth in claim 9, the video processor comprising a burst circuit, the burst circuit configured to identify a burst flag in the composite signal, perform an analog-to-digital conversion on one of the paths and amplify the digitized path.

15. The system as set forth in claim 9, further comprising a main video channel configured to output the upgraded video image and an uncorrected video image in the composite video signal.

16. The system as set forth in claim 9, the video processor comprising:
an automatic frequency suppressor circuit;
an enhanced frequency switch; and
a plurality of delay paths.

17. A method for enhancing video, the method comprising:
receiving a video signal according to a standard;
separating the video signal into a number of component signals;
performing special processing on respective component signals; and
combining the respective component signals to form an upgraded video signal.

18. The method as set forth in claim 17, wherein the special processing comprises performing an additive light function on a combined signal comprising at least two of the separate components.

19. The method as set forth in claim 17, wherein the special processing comprises performing a high-knee gamma function on one of the separate components, the high-knee gamma function comprising a high-knee in a parabolic curve.

20. The method as set forth in claim 17, wherein the special processing comprises performing a flashlight function on one of the separate components.
